(19) United States
(12) Patent Application Publication
(10) Pub. No.: US 2022/0208674 A1
(43) Pub. Date: Jun. 30, 2022

(54) INSULATING CHIP

(71) Applicant: ROHM Co., LTD., Kyoto (JP)

(72) Inventors: Keiji WADA, Kyoto (JP); Yasushi HAMAZAWA, Kyoto (JP)

(21) Appl. No.: 17/645,357

(22) Filed: Dec. 21, 2021

(30) Foreign Application Priority Data
Dec. 24, 2020 (JP) 2020-215444

(51) Int. Cl. H01L 23/522

(52) U.S. Cl. CPC H01L 23/5227

(57) ABSTRACT

Provided is a gate driver that applies a gate voltage to a gate of a switching element, the gate driver including a low voltage circuit that operates when a first voltage is applied, a high voltage circuit that operates when a second voltage is applied, and an insulating chip, in which the insulating chip includes a substrate, an insulating layer, a first insulating element including a first conductor and a second conductor embedded into the insulating layer and arranged to face each other, and a second insulating element including a third conductor and a fourth conductor embedded into the insulating layer and arranged to face each other, and the low voltage circuit and the high voltage circuit are connected through the first insulating element and the second insulating element connected to each other in series and are configured to transmit signals through the first and second insulating elements.

### CROSS REFERENCE TO RELATED APPLICATIONS

This application claims priority benefit of Japanese Patent Application No. JP 2020-215444 filed in the Japan Patent Office on Dec. 24, 2020. Each of the above-referenced applications is hereby incorporated herein by reference in its entirety.

### BACKGROUND

The present disclosure relates to a gate driver.

An isolated gate driver is known as an example of a gate driver that applies a gate voltage to the gate of a switching element such as a transistor. For example, a semiconductor integrated circuit is described in Japanese Patent Laid-Open No. 2013-51547. The semiconductor integrated circuit is an isolated gate driver including transformers having a first coil on the primary side and a second coil on the secondary side.

### SUMMARY

The gate driver may include a low voltage circuit that operates when a first voltage is applied and a high voltage circuit that operates when a second voltage higher than the first voltage is applied. In this case, insulating elements, such as transformers, are used to insulate the low voltage circuit and the high voltage circuit. An improvement in dielectric voltage may be demanded in the gate driver.

According to an embodiment of the present disclosure, there is provided a gate driver that applies a gate voltage to a gate of a switching element, the gate driver including a low voltage circuit that operates when a first voltage is applied, a high voltage circuit that operates when a second voltage higher than the first voltage is applied, and an insulating chip. The insulating chip includes a substrate, an insulating layer formed on the substrate, a first insulating element including a first conductor and a second conductor embedded into the insulating layer and arranged to face each other, and a second insulating element including a third conductor and a fourth conductor embedded into the insulating layer and arranged to face each other. The low voltage circuit and the high voltage circuit are connected through the first insulating element and the second insulating element connected to each other in series and are configured to transmit signals through the first insulating element and the second insulating element.

According to the configuration, the low voltage circuit and the high voltage circuit are connected through the first insulating element and the second insulating element connected to each other in series and are configured to transmit signals through the insulating elements. This can improve the dielectric voltage of the gate driver compared to a case in which there is one insulating element.

According to the configuration, the first insulating element and the second insulating element are provided in one insulating chip. In other words, a chip dedicated to the first insulating element and the second insulating element is provided. Thus, a common insulating chip can be used for a low voltage circuit and a high voltage circuit that are different. This can reduce the cost of manufacturing a plurality of types of gate drivers in which at least one of the low voltage circuit and the high voltage circuit is different.

According to an embodiment of the gate driver, the dielectric voltage can be improved.

### BRIEF DESCRIPTION OF THE DRAWINGS

FIG. 1 is a schematic circuit diagram of a gate driver in a first embodiment;

FIG. 2 is a plan view illustrating an internal configuration of the gate driver in the first embodiment;

FIG. 3 is a schematic cross-sectional view of a transformer chip in FIG. 2;

FIG. 4 is a plan view illustrating an internal configuration of a gate driver in a comparison example;

FIG. 5 is a schematic circuit diagram of the gate driver in a second embodiment;

FIG. 6 is a plan view illustrating an internal configuration of the gate driver in the second embodiment;

FIG. 7 is a schematic cross-sectional view of a capacitor chip in FIG. 6;

FIG. 8 is a schematic cross-sectional view of the transformer chip in a modification example;

FIG. 9 is a schematic cross-sectional view of the transformer chip in a modification example;

FIG. 10 is a schematic cross-sectional view of the transformer chip in a modification example;

FIG. 11 is a schematic plan view illustrating transformers and the surroundings of the transformers in the transformer chip of a modification example;

FIG. 12 is a schematic cross-sectional view of the transformer chip in FIG. 11 taken along line 12-12; and

FIG. 13 is a schematic circuit diagram of the gate driver in a modification example.

### DETAILED DESCRIPTION OF THE PREFERRED EMBODIMENTS

Embodiments of a gate driver will now be described with reference to the drawings. The following embodiments illustrate configurations and methods for embodying technical ideas, but the embodiments are not intended to limit the materials, shapes, structures, arrangements, and dimensions of constituent parts to the ones described below.

### First Embodiment

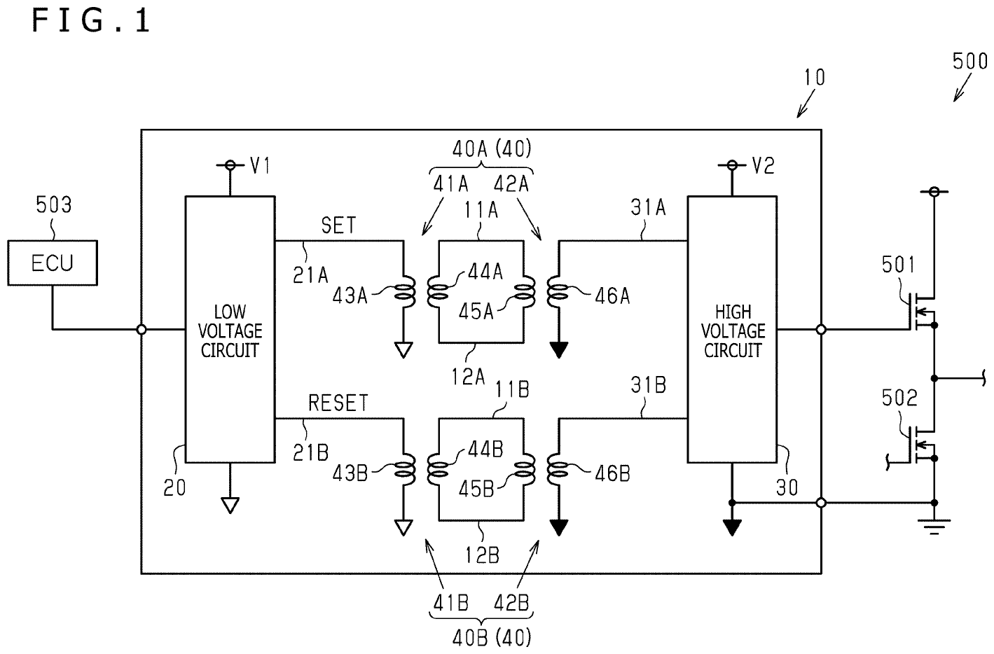

A gate driver 10 of a first embodiment will be described with reference to FIGS. 1 to 4. FIG. 1 illustrates an example of a simplified circuit configuration of the gate driver 10.

As illustrated in FIG. 1, the gate driver 10 is configured to apply a gate voltage to a gate of a switching element, and the gate driver 10 is applied to, for example, an inverter apparatus 500 mounted on an electric car or a hybrid car. The inverter apparatus 500 includes a pair of switching elements 501 and 502 connected to each other in series, the gate driver 10, and an electronic control unit (ECU) 503 that controls the gate driver 10. The switching element 501 is a high-side switching element connected to, for example, a driving power supply, and the switching element 502 is a low-side switching element. Examples of the switching elements 501 and 502 include transistors, such as a silicon metal oxide semiconductor field-effect transistor (SiMOSFET), a silicon carbide MOSFET (SiCMOSFET), and an insulated gate bipolar transistor (IGBT). The gate driver 10 of the present embodiment applies a gate voltage to the gate of the switching element 501. Note that MOSFETs are used as the switching elements 501 and 502 in the case described below.

The gate driver 10 is provided for each of the switching elements 501 and 502, and the gate drivers 10 individually drive the switching elements 501 and 502. In the present embodiment, the gate driver 10 that drives the switching element 501 will be described for the convenience of description.

The gate driver 10 includes a low voltage circuit 20 to which a first voltage V1 is applied; a high voltage circuit 30 to which a second voltage V2 higher than the first voltage V1 is applied; and transformers 40 provided between the low voltage circuit 20 and the high voltage circuit 30. That is, the low voltage circuit 20 and the high voltage circuit 30 are connected through the transformers 40. The first voltage V1 and the second voltage V2 are direct current (DC) voltages.

In the gate driver 10 of the present embodiment, signals are transmitted from the low voltage circuit 20 to the high voltage circuit 30 through the transformers 40 on the basis of a control signal from the ECU 503 as an external control apparatus, and the gate voltage is output from the high voltage circuit 30. The control signal from the ECU 503 here corresponds to the external command.

The signals transmitted from the low voltage circuit 20 toward the high voltage circuit 30, that is, the signals output from the low voltage circuit 20, are, for example, signals for driving the switching element 501, and an example of the signals includes a set signal and a reset signal. The set signal is a signal for transmitting a rise of the control signal from the ECU 503, and the reset signal is a signal for transmitting a fall of the control signal from the ECU 503. The set signal and the reset signal can also be described as signals for generating the gate voltage of the switching element 501. Thus, the set signal and the reset signal correspond to the first signal.

More specifically, the low voltage circuit 20 is a circuit that operates when the first voltage V1 is applied. The low voltage circuit 20 is a circuit electrically connected to the ECU 503, and the low voltage circuit 20 generates a set signal and a reset signal on the basis of the control signal input from the ECU 503. For example, the low voltage circuit 20 generates a set signal in response to a rise of the control signal and generates a reset signal in response to a fall of the control signal. The low voltage circuit 20 then transmits the generated set signal and reset signal toward the high voltage circuit 30.

The high voltage circuit 30 is a circuit that operates when the second voltage V2 is applied. The high voltage circuit 30 is a circuit electrically connected to the gate of the switching element 501. The high voltage circuit 30 generates a gate voltage for driving the switching element 501, on the basis of the set signal and the reset signal received from the low voltage circuit 20, and applies the gate voltage to the gate of the switching element 501. The high voltage circuit 30 can also be described to generate, on the basis of the first signal output from the low voltage circuit 20, a gate voltage to be applied to the gate of the switching element 501. More specifically, the high voltage circuit 30 generates a gate voltage for turning on the switching element 501, on the basis of the set signal, and applies the gate voltage to the gate of the switching element 501. The high voltage circuit 30 also generates a gate voltage for turning off the switching element 501, on the basis of the reset signal, and applies the gate voltage to the gate of the switching element 501. In this way, the gate driver 10 controls on/off of the switching element 501.

The high voltage circuit 30 includes, for example, a reset set (RS) flip-flop circuit that receives the set signal and the reset signal and a driver unit that generates the gate voltage on the basis of the output signal of the RS flip-flop circuit. However, the specific circuit configuration of the high voltage circuit 30 may have any configuration.

In the gate driver 10 of the present embodiment, the low voltage circuit 20 and the high voltage circuit 30 are insulated by the transformers 40. More specifically, while the transmission of DC voltage between the low voltage circuit 20 and the high voltage circuit 30 is regulated by the transformers 40, various signals, such as a set signal and a reset signal, can be transmitted.

That is, the state in which the low voltage circuit 20 and the high voltage circuit 30 are insulated denotes a state of cutting off the transmission of DC voltage between the low voltage circuit 20 and the high voltage circuit 30, and the transmission of signals between the low voltage circuit 20 and the high voltage circuit 30 is permitted.

The dielectric voltage of the gate driver 10 is, for example, equal to or greater than 2500 Vrms but equal to or smaller than 7500 Vrms. The dielectric voltage of the gate driver 10 in the present embodiment is approximately 5000 Vrms. However, the specific value of the dielectric voltage of the gate driver 10 is not limited to this and may be set to any value.

In the present embodiment, the ground of the low voltage circuit 20 and the ground of the high voltage circuit 30 are independently provided. Hereinafter, the ground potential of the low voltage circuit 20 will be referred to as a first reference potential, and the ground potential of the high voltage circuit 30 will be referred to as a second reference potential. In this case, the first voltage V1 is a voltage based on the first reference potential, and the second voltage V2 is a voltage based on the second reference potential. The first voltage V1 is, for example, equal to or greater than 4.5 V but equal to or smaller than 5.5 V, and the second voltage V2 is, for example, equal to or greater than 9 V but equal to or smaller than 24 V.

The transformers 40 will next be described in detail.

The gate driver 10 of the present embodiment includes two transformers 40, corresponding to the transmission of two types of signals from the low voltage circuit 20 toward the high voltage circuit 30. More specifically, the gate driver 10 includes a transformer 40 used to transmit the set signal and a transformer 40 used to transmit the reset signal. Hereinafter, the transformer 40 used to transmit the set signal will be referred to as a transformer 40A, and the transformer 40 used to transmit the reset signal will be referred to as a transformer 40B for the convenience of description.

The gate driver 10 includes a low voltage signal line 21A connecting the low voltage circuit 20 and the transformer 40A and a low voltage signal line 21B connecting the low voltage circuit 20 and the transformer 40B. Accordingly, the low voltage signal line 21A transmits the set signal from the low voltage circuit 20 to the transformer 40A. The low voltage signal line 21B transmits the reset signal from the low voltage circuit 20 to the transformer 40B.

The gate driver 10 includes a high voltage signal line 31A connecting the transformer 40A and the high voltage circuit 30 and a high voltage signal line 31B connecting the transformer 40B and the high voltage circuit 30. Accordingly, the high voltage signal line 31A transmits the set signal from the transformer 40A to the high voltage circuit 30. The high voltage signal line 31B transmits the reset signal from the transformer 40B to the high voltage circuit 30.

The transformer 40A transmits the set signal from the low voltage circuit 20 to the high voltage circuit 30 and also electrically insulates the low voltage circuit 20 and the high voltage circuit 30. The transformer 40A includes a first transformer 41A and a second transformer 42A connected to each other in series. In the present embodiment, the first transformer 41A corresponds to the first insulating element, and the second transformer 42A corresponds to the second insulating element.

The gate driver 10 includes a pair of connection signal lines 11A and 12A connecting the first transformer 41A and the second transformer 42A. Accordingly, the pair of connection signal lines 11A and 12A are signal lines for transmitting the set signal.

The dielectric voltages of the transformers 41A and 42A in the present embodiment are, for example, equal to or greater than 2500 Vrms but equal to or smaller than 7500 Vrms. Note that the dielectric voltages of the transformers 41A and 42A may be equal to or greater than 2500 Vrms but equal to or smaller than 5700 Vrms. The dielectric voltage of the second transformer 42A in the present embodiment is set lower than the dielectric voltage of the first transformer 41A. However, the dielectric voltages of the transformers 41A and 42A are not limited to these, and can be set to any voltage.

The first transformer 41A includes a first coil 43A and a second coil 44A that is electrically insulated from the first coil 43A and that can be magnetically coupled to the first coil 43A. The second transformer 42A includes a first coil 45A and a second coil 46A that is electrically insulated from the first coil 45A and that can be magnetically coupled to the first coil 45A.

The first coil 43A is connected to the low voltage circuit 20 through the low voltage signal line 21A and is also connected to the ground of the low voltage circuit 20. That is, a first end of the first coil 43A is electrically connected to the low voltage circuit 20, and a second end of the first coil 43A is electrically connected to the ground of the low voltage circuit 20. Thus, the potential of the second end of the first coil 43A is the first reference potential. The first reference potential is, for example, 0 V.

The second coil 44A is connected to the first coil 45A. The second coil 44A and the first coil 45A are connected to each other in, for example, an electrically floating state. That is, a first end of the second coil 44A and a first end of the first coil 45A are connected through the connection signal line 11A. A second end of the second coil 44A and a second end of the first coil 45A are connected through the connection signal line 12A. In this way, the second coil 44A and the first coil 45A are relay coils that relay the transmission of signals between the first coil 43A and the second coil 46A.

The second coil 46A is connected to the high voltage circuit 30 through the high voltage signal line 31A and is also connected to the ground of the high voltage circuit 30. That is, a first end of the second coil 46A is electrically connected to the high voltage circuit 30, and a second end of the second coil 46A is electrically connected to the ground of the high voltage circuit 30. Thus, the potential of the second end of the second coil 46A is the second reference potential. The ground of the high voltage circuit 30 is connected to the source of the switching element 501. Thus, the second reference potential varies according to driving of the inverter apparatus 500, and the second reference potential may become, for example, equal to or greater than 600 V.

The transformer 40B transmits the reset signal from the low voltage circuit 20 to the high voltage circuit 30 and also electrically insulates the low voltage circuit 20 and the high voltage circuit 30. The transformer 40B includes a first transformer 41B and a second transformer 42B connected to each other in series. In the present embodiment, the first transformer 41B corresponds to the first insulating element, and the second transformer 42B corresponds to the second insulating element.

The gate driver 10 includes a pair of connection signal lines 11B and 12B connecting the first transformer 41B and the second transformer 42B. Accordingly, the pair of connection signal lines 11B and 12B are signal lines for transmitting the reset signal.

The first transformer 41B includes a first coil 43B and a second coil 44B that is electrically insulated from the first coil 43B and that can be magnetically coupled to the first coil 43B. The second transformer 42B includes a first coil 45B and a second coil 46B that is electrically insulated from the first coil 45B and that can be magnetically coupled to the first coil 45B. The dielectric voltage of the first transformer 41B is the same as the dielectric voltage of the first transformer 41A, and the dielectric voltage of the second transformer 42B is the same as the dielectric voltage of the second transformer 42A. Note that the connection configuration of the first transformer 41B and the second transformer 42B is similar to the connection configuration of the first transformer 41A and the second transformer 42A, and the detailed description will not be repeated.

The set signal output from the low voltage circuit 20 is transmitted to the high voltage circuit 30 through the first transformer 41A and the second transformer 42A. The reset signal output from the low voltage circuit 20 is transmitted to the high voltage circuit 30 through the first transformer 41B and the second transformer 42B.

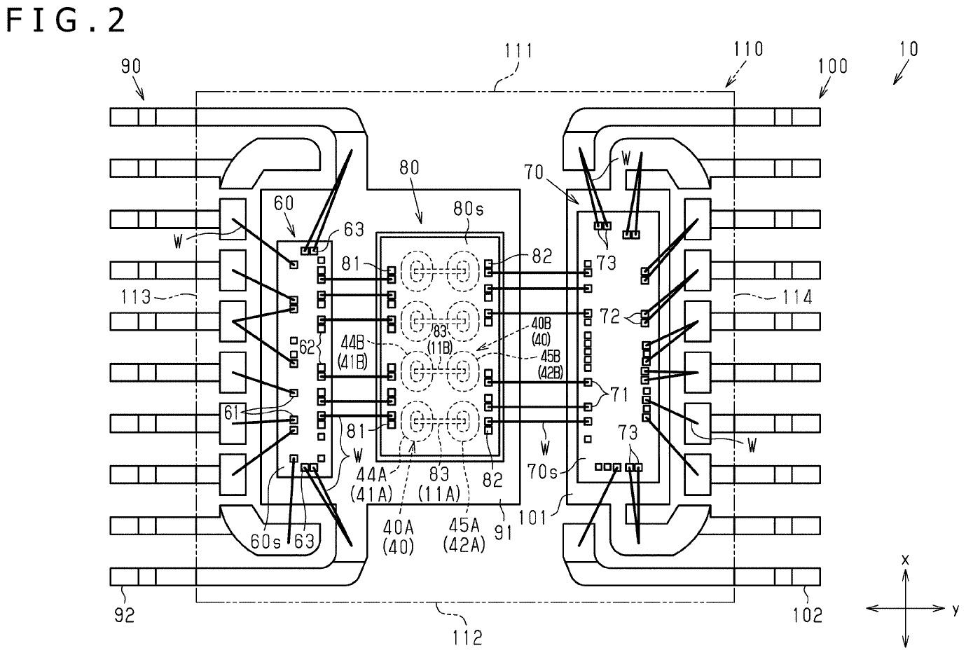

FIG. 2 illustrates an example of a plan view illustrating an internal configuration of the gate driver 10. Note that the circuit configuration of the gate driver 10 is simplified in FIG. 1, and thus, the number of external terminals of the gate driver 10 in FIG. 2 is greater than the number of external terminals of the gate driver 10 in FIG. 1. The number of external terminals of the gate driver 10 here is the number of external electrodes that can connect the gate driver 10 and electronic parts provided outside of the gate driver 10, such as the ECU 503 and the switching element 501 (see FIG. 1). The number of signal lines (the number of wires W described later) for transmitting signals from the low voltage circuit 20 to the high voltage circuit 30 in the gate driver 10 of FIG. 2 is greater than the number of signal lines of the gate driver 10 in FIG. 1.

As illustrated in FIG. 2, the gate driver 10 is a semiconductor apparatus including a plurality of semiconductor chips in one package, and the gate driver 10 is mounted on, for example, a circuit board provided on the inverter apparatus 500. Note that the switching elements 501 and 502 are mounted on a mount board different from the circuit board. A cooler is attached to the mount board.

The package format of the gate driver 10 is a small outline (SO) system, which is a small outline package (SOP) in the present embodiment. The gate driver 10 includes a low voltage circuit chip 60, a high voltage circuit chip 70, and a transformer chip 80 that are semiconductor chips; a low voltage lead frame 90 provided with the low voltage circuit chip 60; a high voltage lead frame 100 provided with the high voltage circuit chip 70; and a sealing resin 110 that seals part of the lead frames 90 and 100 and the chips 60, 70, and 80. In the present embodiment, the transformer chip 80 corresponds to the insulating chip that insulates the low voltage circuit 20 and the high voltage circuit 30. In FIG. 2, the sealing resin 110 is indicated by a two dot chain line for the convenience of describing the internal structure of the gate driver 10. The package format of the gate driver 10 can be changed to any format.

The sealing resin 110 contains an electrically insulating material, such as a black epoxy resin. The sealing resin 110 is formed in a rectangular plate shape with a z direction as a thickness direction. The sealing resin 110 includes four resin side surfaces 111 to 114. More specifically, the sealing resin 110 includes the resin side surfaces 111 and 112 as end surfaces in an x direction and the resin side surfaces 113 and 114 as end surfaces in a y direction. The x direction and the y direction are directions orthogonal to the z direction. The x direction and the y direction are orthogonal to each other. Note that, in the following description, “in plan view” denotes a view from the z direction.

Each of the low voltage lead frame 90 and the high voltage lead frame 100 includes a conductor and contains Cu (copper) in the present embodiment. The lead frames 90 and 100 are provided across the inside and outside of the sealing resin 110.

The low voltage lead frame 90 includes a low voltage die pad 91 arranged in the sealing resin 110 and a plurality of low voltage leads 92 arranged across the inside and outside of the sealing resin 110. Each low voltage lead 92 provides an external terminal for electrical connection to an external electronic device such as the ECU 503 (see FIG. 1).

On the low voltage die pad 91, the low voltage circuit chip 60 and the transformer chip 80 are mounted. The low voltage die pad 91 is arranged such that the center of the low voltage die pad 91 in the y direction is closer to the resin side surface 113 than the center of the sealing resin 110 in the y direction in plan view. In the present embodiment, the low voltage die pad 91 is not exposed from the sealing resin 110. The shape of the low voltage die pad 91 in plan view is a rectangular shape, in which the x direction is the long side direction and the y direction is the short side direction.

The plurality of low voltage leads 92 are separately arrayed in the x direction. Among the plurality of low voltage leads 92, the low voltage leads 92 arranged on both ends in the x direction are integrated with the low voltage die pad 91. Part of each low voltage lead 92 protrudes outside the sealing resin 110 from the resin side surface 113.

The high voltage lead frame 100 includes a high voltage die pad 101 arranged in the sealing resin 110 and a plurality of high voltage leads 102 arranged across the inside and outside of the sealing resin 110. Each high voltage lead 102 provides an external terminal for electrical connection to an external electronic device such as the gate of the switching element 501 (see FIG. 1).

On the high voltage die pad 101, the high voltage circuit chip 70 is mounted. The high voltage die pad 101 is arranged closer to the resin side surface 114 than the low voltage die pad 91 in the y direction in plan view. In the present embodiment, the high voltage die pad 101 is not exposed from the sealing resin 110. The shape of the high voltage die pad 101 in plan view is a rectangular shape, in which the x direction is the long side direction and the y direction is the short side direction.

The low voltage die pad 91 and the high voltage die pad 101 are separately arrayed in the y direction. Thus, the y direction can also be described as the array direction of the die pads 91 and 101.

The dimensions of the low voltage die pad 91 and the high voltage die pad 101 in the y direction are set according to the sizes and the number of mounted semiconductor chips. In the present embodiment, the low voltage circuit chip 60 and the transformer chip 80 are mounted on the low voltage die pad 91, and the high voltage circuit chip 70 is mounted on the high voltage die pad 101. Thus, the dimension of the low voltage die pad 91 in the y direction is larger than the dimension of the high voltage die pad 101 in the y direction.

The plurality of high voltage leads 102 are separately arrayed in the x direction. A pair of high voltage leads 102 among the plurality of high voltage leads 102 are integrated with the high voltage die pad 101. Part of each high voltage lead 102 protrudes outside the sealing resin 110 from the resin side surface 114.

In the present embodiment, the number of high voltage leads 102 is the same as the number of low voltage leads 92. As can be understood from FIG. 2, the plurality of low voltage leads 92 and the plurality of high voltage leads 102 are arrayed in the direction (x direction) orthogonal to the array direction (y direction) of the low voltage die pad 91 and the high voltage die pad 101. Note that the number of high voltage leads 102 and the number of low voltage leads 92 can be changed to any number.

In the present embodiment, the low voltage die pad 91 is supported by the pair of low voltage leads 92 integrated with the low voltage die pad 91, and the high voltage die pad 101 is supported by the pair of high voltage leads 102 integrated with the high voltage die pad 101. Thus, the die pads 91 and 101 are not provided with support leads exposed on the resin side surfaces 111 and 112. As a result, the creepage distance between the low voltage lead frame 90 and the high voltage lead frame 100 can be large.

The low voltage circuit chip 60, the high voltage circuit chip 70, and the transformer chip 80 are separately arrayed in the y direction. The low voltage circuit chip 60, the transformer chip 80, and the high voltage circuit chip 70 are arrayed in this order from the low voltage lead 92 toward the high voltage lead 102 in the y direction.

The low voltage circuit chip 60 includes the low voltage circuit 20 illustrated in FIG. 1. The shape of the low voltage circuit chip 60 in plan view is a rectangular shape including short sides and long sides. The low voltage circuit chip 60 is mounted on the low voltage die pad 91 such that the long sides are along the x direction and the short sides are along the y direction in plan view. The low voltage circuit chip 60 includes a chip main surface 60s and a chip back surface (not illustrated) facing opposite sides in the z direction. A conductive bonding material, such as solder and Ag (silver) paste, is used to bond the chip back surface of the low voltage circuit chip 60 to the low voltage die pad 91.

A plurality of first electrode pads 61, a plurality of second electrode pads 62, and a plurality of third electrode pads 63 are formed on the chip main surface 60s of the low voltage circuit chip 60. The electrode pads 61 to 63 are electrically connected to the low voltage circuit 20.

The plurality of first electrode pads 61 are arranged on the chip main surface 60s, closer to the low voltage lead 92 than the center of the chip main surface 60s in the y direction. The plurality of first electrode pads 61 are arrayed in the x direction. The plurality of second electrode pads 62 are arranged on one of the ends of the chip main surface 60s in the y direction that is closer to the transformer chip 80. The plurality of second electrode pads 62 are arrayed in the x direction. The plurality of third electrode pads 63 are arranged on both ends of the chip main surface 60s in the x direction.

The high voltage circuit chip 70 includes the high voltage circuit 30 illustrated in FIG. 1. The shape of the high voltage circuit chip 70 in plan view is a rectangular shape including short sides and long sides. The high voltage circuit chip 70 is mounted on the high voltage die pad 101 such that the long sides are along the x direction and the short sides are along the y direction in plan view. The high voltage circuit chip 70 includes a chip main surface 70s and a chip back surface (not illustrated) facing opposite sides in the z direction. A conductive bonding material is used to bond the chip back surface of the high voltage circuit chip 70 to the high voltage die pad 101.

A plurality of first electrode pads 71, a plurality of second electrode pads 72, and a plurality of third electrode pads 73 are formed on the chip main surface 70s of the high voltage circuit chip 70. The electrode pads 71 to 73 are electrically connected to the high voltage circuit 30.

The plurality of electrode pads 71 are arranged on one of the ends of the chip main surface 70s in the y direction that is closer to the transformer chip 80. The plurality of first electrode pads 71 are arrayed in the x direction. The plurality of second electrode pads 72 are arranged on one of the ends of the chip main surface 70s in the y direction that is farther from the transformer chip 80. The plurality of second electrode pads 72 are arrayed in the x direction. The plurality of third electrode pads 73 are arranged on both ends of the chip main surface 70s in the x direction.

The transformer chip 80 includes the transformers 40. The shape of the transformer chip 80 in plan view is a rectangular shape including short sides and long sides. In the present embodiment, the transformer chip 80 is provided on the low voltage die pad 91 such that the long sides are along the x direction and the short sides are along the y direction in plan view.

The transformer chip 80 is arranged next to the low voltage circuit chip 60 in the y direction. The transformer chip 80 is arranged at a position closer to the high voltage circuit chip 70 than the low voltage circuit chip 60.

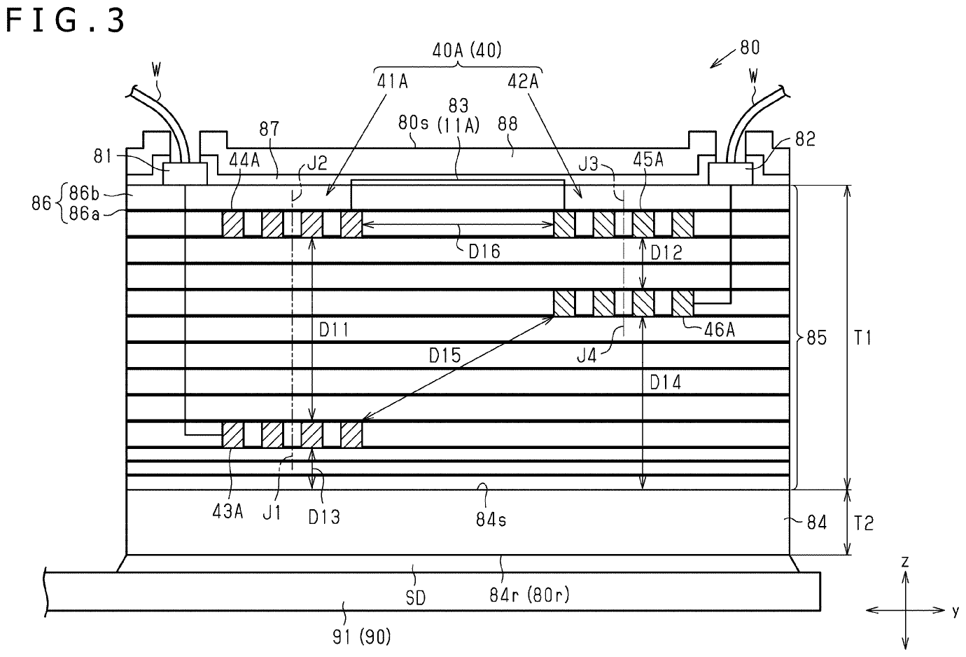

As illustrated in FIG. 3, the transformer chip 80 includes a chip main surface 80s and a chip back surface 80r facing opposite sides in the z direction. A conductive bonding material SD is used to bond the chip back surface 80r of the transformer chip 80 to the low voltage die pad 91.

As illustrated in FIG. 2, a plurality of first electrode pads 81 and a plurality of second electrode pads 82 are formed on the chip main surface 80s of the transformer chip 80. The transformer chip 80 includes a plurality of connection wires 83. The plurality of first electrode pads 81 are arranged on, for example, one of the ends of the chip main surface 80s in the y direction that is closer to the low voltage circuit chip 60. The plurality of first electrode pads 81 are arrayed in the x direction. The plurality of second electrode pads 82 are arranged on, for example, one of the ends of the chip main surface 80s in the y direction that is closer to the high voltage circuit chip 70. The plurality of second electrode pads 82 are arrayed in the x direction. The transformers 40A and 40B are arranged between the plurality of first electrode pads 81 and the plurality of second electrode pads 82 in the y direction. The plurality of connection wires 83 are arranged inside of ends of the chip main surface 80s in the y direction. The electrode pads 81 and 82 and the connection wires 83 are electrically connected to the transformers 40A and 40B.

To set the dielectric voltage of the gate driver 10 to the preset dielectric voltage, the low voltage die pad 91 and the high voltage die pad 101, to which the lead frames 90 and 100 are closest, may need to be separated from each other. Thus, the distance between the high voltage circuit chip 70 and the transformer chip 80 is larger than the distance between the low voltage circuit chip 60 and the transformer chip 80 in plan view.

A plurality of wires W are connected to each of the low voltage circuit chip 60, the transformer chip 80, and the high voltage circuit chip 70. The wires W are bonding wires formed by a wire bonding apparatus, and the wires W include, for example, conductors of Au (gold), Al (aluminum), or Cu.

The low voltage circuit chip 60 is electrically connected to the low voltage lead frame 90 through the wires W. More specifically, the plurality of first electrode pads 61 of the low voltage circuit chip 60 and the plurality of low voltage leads 92 are connected through the wires W. The plurality of third electrode pads 63 of the low voltage circuit chip 60 and a pair of low voltage leads 92 integrated with the low voltage die pad 91 among the plurality of low voltage leads 92 are connected through the wires W. In this way, the low voltage circuit 20 (see FIG. 1) and the plurality of low voltage leads 92 (external electrodes electrically connected to the ECU 503 among the external electrodes of the gate driver 10) are electrically connected. In the present embodiment, the pair of low voltage leads 92 integrated with the low voltage die pad 91 provide ground terminals, and the low voltage circuit 20 and the low voltage die pad 91 are electrically connected through the wires W. Thus, the potential of the low voltage die pad 91 is the same as the potential of the ground of the low voltage circuit 20.

The high voltage circuit chip 70 and the plurality of high voltage leads 102 of the high voltage lead frame 100 are electrically connected through the wires W. More specifically, the plurality of second electrode pads 72 and the plurality of third electrode pads 73 of the high voltage circuit chip 70 are connected to the high voltage leads 102 through the wires W. In this way, the high voltage circuit 30 (see FIG. 1) and the plurality of high voltage leads 102 (external electrodes electrically connected to the inverter apparatus 500, such as the switching element 501, among the external electrodes of the gate driver 10) are electrically connected. In the present embodiment, the pair of high voltage leads 102 integrated with the high voltage die pad 101 provide ground terminals, and the high voltage circuit 30 and the high voltage die pad 101 are electrically connected through the wires W. Thus, the potential of the high voltage die pad 101 is the same as the potential of the ground of the high voltage circuit 30.

The transformer chip 80 is connected to both the low voltage circuit chip 60 and the high voltage circuit chip 70 through the wires W. More specifically, the first electrode pads 81 of the transformer chip 80 are connected to the second electrode pads 62 of the low voltage circuit chip 60 through the wires W. The second electrode pads 82 of the transformer chip 80 are connected to the first electrode pads 71 of the high voltage circuit chip 70 through the wires W.

Note that both the first coil 43A of the transformer 40A and the first coil 43B of the transformer 40B (see FIG. 1) are electrically connected to the ground of the low voltage circuit 20 through the wires W, the low voltage circuit chip 60, and other components. Both the second coil 46A of the transformer 40A and the second coil 46B of the transformer 40B (see FIG. 1) are electrically connected to the ground of the high voltage circuit 30 through the wires W, the high voltage circuit chip 70, and other components.

An example of the internal structure of the transformer chip 80 will be described with reference to FIG. 3. FIG. 3 illustrates a schematic cross-sectional structure of the transformer 40A in the transformer chip 80. Note that the configuration of the transformer 40B is the same as the configuration of the transformer 40A, and the description will not be repeated. In the following description, the direction from the chip back surface 80r toward the chip main surface 80s of the transformer chip 80 will be referred to as “above,” and the direction from the chip main surface 80s toward the chip back surface 80r will be referred to as “below.”

As illustrated in FIG. 3, the transformer chip 80 includes both the transformers 40A and 40B (see FIG. 1), and more specifically, the transformer chip 80 is provided by forming a chip including both the transformers 40A and 40B. That is, the transformer chip 80 is a chip dedicated to the transformers 40A and 40B, different from the low voltage circuit chip 60 and the high voltage circuit chip 70. As illustrated in FIG. 2, the transformer chip 80 is mounted in a state in which the first transformer 41A of the transformer 40A and the first transformer 41B of the transformer 40B are arranged closer to the low voltage circuit chip 60 and the second transformer 42A of the transformer 40A and the second transformer 42B of the transformer 40B are arranged closer to the high voltage circuit chip 70.

As illustrated in FIG. 3, the transformer chip 80 includes a substrate 84 and an insulating layer laminated body 85 formed on the substrate 84.

The substrate 84 includes, for example, a semiconductor substrate, and the substrate 84 is a substrate formed from a material containing Si (silicon) in the present embodiment. The substrate 84 includes a substrate main surface 84s and a substrate back surface 84r facing opposite sides in the z direction. The substrate back surface 84r provides the chip back surface 80r of the transformer chip 80.

The insulating layer laminated body 85 includes a plurality of insulating layers 86 laminated in the z direction, each insulating layer 86 including a first insulating layer 86a and a second insulating layer 86b laminated on the first insulating layer 86a. That is, the z direction is the thickness direction of the insulating layer laminated body 85. Moreover, the z direction can also be described as the thickness direction of the insulating layer 86. The insulating layer 86 is formed on the substrate main surface 84s of the substrate 84.

The first insulating layer 86a is, for example, an etching stopper film, and includes an SiN film, an SiC film, an SiCN film, or other films. In the present embodiment, the first insulating layer 86a includes an SiN film. The second insulating layer 86b is, for example, an interlayer insulating film and includes an SiO₂ film. Note that the lowermost insulating layer 86 in contact with the substrate main surface 84s of the substrate 84 includes the second insulating layer 86b. A thickness T1 of the insulating layer laminated body 85 is thicker than a thickness T2 of the substrate 84.

The first transformer 41A and the second transformer 42A are embedded into the insulating layer 86. As illustrated in FIGS. 2 and 3, the first transformer 41A and the second transformer 42A are in line with each other in the x direction and separately arrayed in the y direction. The first transformer 41A and the second transformer 42A can also be described as being separately arrayed in the array direction of the chips 60, 70, and 80.

The first coil 43A and the second coil 44A of the first transformer 41 are arranged to face each other in the z direction through the insulating layer 86. In the present embodiment, the first coil 43A and the second coil 44A are arranged to face each other in the z direction through the plurality of insulating layers 86. The coils 43A and 44A are provided as conductive layers embedded into one insulating layer 86. More specifically, a groove going through both the first insulating layer 86a and the second insulating layer 86b in the z direction is formed on the insulating layer 86 provided with the coils 43A and 44A. The conductive layers included in the coils 43A and 44A are embedded into the groove of the insulating layer 86.

In other words, the first coil 43A and the second coil 44A are embedded into the insulating layer laminated body 85 including the plurality of laminated insulating layers 86. That is, the first coil 43A and the second coil 44A of the present embodiment can also be described as being separately arranged to face each other through one or a plurality of insulating layers 86 and embedded into the insulating layer laminated body 85 including a plurality of insulating layers 86.

The second coil 44A is at a position farther from the substrate 84 than the first coil 43A in the z direction. In other words, the second coil 44A is positioned above the first coil 43A. It can also be described that the first coil 43A is arranged closer to the substrate 84 than the second coil 44A in the z direction. In the present embodiment, the second coil 44A corresponds to the second conductor of the first insulating element, and the first coil 43A corresponds to the first conductor of the first insulating element.

The first coil 45A and the second coil 46A of the second transformer 42A are arranged to face each other in the z direction through the insulating layer 86. The coils 45A and 46A are provided as conductive layers embedded into one insulating layer 86, similarly to the coils 43A and 44A. The first coil 45A is at a position farther from the substrate 84 than the second coil 46A in the z direction. In other words, the first coil 45A is positioned above the second coil 46A. It can also be described that the second coil 46A is arranged closer to the substrate 84 than the first coil 45A in the z direction. In the present embodiment, the first coil 45A corresponds to the fourth conductor of the second insulating element, and the second coil 46A corresponds to the third conductor of the second insulating element. Further, the first coil 45A corresponds to the fourth coil, and the second coil 46A corresponds to the third coil.

The transformer chip 80 further includes a protection film 87 formed on the insulating layer laminated body 85 and a passivation film 88 formed on the protection film 87. The protection film 87 is a film that protects the insulating layer laminated body 85, and the protection film 87 includes, for example, an SiO₂ film. The passivation film 88 is a surface protection film of the transformer chip 80, and the passivation film 88 includes, for example, an SiN film. The passivation film 88 provides the chip main surface 80s of the transformer chip 80.

The plurality of first electrode pads 81, the plurality of second electrode pads 82, and the plurality of connection wires 83 are formed on the insulating layer laminated body 85. The connection wires 83 contain, for example, Al. Both the protection film 87 and the passivation film 88 are formed to cover the peripheries of the upper surfaces of the pads 81 and 82 and to cover the connection wires 83. Thus, on each of the pads 81 and 82, an exposed surface for connecting the wire W thereto is formed.

A first end of the first coil 43A is electrically connected to the first electrode pad 81 used for establishing electrical connection to the low voltage circuit 20. In this way, the low voltage circuit 20 and the first coil 43A are electrically connected. On the other hand, a second end of the first coil 43A is electrically connected to the first electrode pad 81 used for establishing electrical connection to the ground of the low voltage circuit 20. In this way, the ground of the low voltage circuit 20 and the first coil 43A are electrically connected.

The second coil 44A and the first coil 45A are connected through the connection wire 83. That is, the ends of the second coil 44A and the first coil 45A are connected through the connection wire 83. Thus, the connection wire 83 connecting the second coil 44A and the first coil 45A provides the connection signal lines 11A and 12A. In this way, the transformer chip 80 includes the connection wire 83 connecting the first transformer 41A and the second transformer 42A in series. In the present embodiment, the connection wire 83 corresponds to the wire.

A first end of the second coil 46A is electrically connected to the second electrode pad 82 used for establishing electrical connection to the high voltage circuit 30. In this way, the high voltage circuit 30 and the second coil 46A are electrically connected. On the other hand, a second end of the second coil 46A is electrically connected to the second electrode pad 82 used for establishing connection to the ground of the high voltage circuit 30. In this way, the ground of the high voltage circuit 30 and the second coil 46A are electrically connected.

As illustrated in FIG. 2, the coils 44A and 45A are formed in an elliptical spiral shape in plan view. Although not illustrated, the coils 43A and 46A are similarly shaped in plan view. The first coil 43A and the second coil 44A are formed in the same winding direction in plan view. As illustrated in FIG. 3, the first coil 45A and the second coil 46A are formed in the same winding direction as viewed from the z direction. The second coil 44A and the first coil 45A are formed in opposite winding directions as viewed from the z direction. The first coil 43A and the second coil 46A are formed in opposite winding directions as viewed from the z direction.

Next, the positional relation between the first coils 43A and 45A and the second coils 44A and 46A in the transformer chip 80 will be described. Note that the positional relation between the first coils 43B and 45B and the second coils 44B and 46B in the transformer chip 80 is similar to the positional relation between the first coils 43A and 45A and the second coils 44A and 46A in the transformer chip 80, and the description will not be repeated.

The positions of the first coils 43A and 45A and the second coils 44A and 46A in the transformer chip 80 are set to bring the dielectric voltage of the transformer chip 80 into line with the preset dielectric voltage.

A distance D11 between the first coil 43A and the second coil 44A is larger than a distance D12 between the first coil 45A and the second coil 46A. For example, the distance D11 is equal to or more than double the distance D12. However, the distances are not limited to these, and the distance D11 may be less than double the distance D12.

In the present embodiment, the second coil 44A and the first coil 45A are arranged at positions in line with each other in the z direction. On the other hand, the second coil 46A is at a position farther from the substrate 84 than the first coil 43A in the z direction (that is, above the first coil 43A). As a result, the distance D11 is larger than the distance D12.

In this case, the second coil 46A is arranged at a position between the first coil 43A and the second coil 44A in the z direction as viewed from the y direction. That is, a distance D14 between the second coil 46A and the substrate 84 is larger than a distance D13 between the first coil 43A and the substrate 84. For example, the distance D14 is equal to or more than double the distance D13. However, the distances are not limited to these, and the distance D14 may be less than double the distance D13.

The second coil 46A is electrically connected to the high voltage die pad 101, and the potential of the ground of the second coil 46A and the potential of the substrate 84 may be different. Thus, the second coil 46A and the substrate 84 may need to be insulated. That is, the distance D14 between the second coil 46A and the substrate 84 can be set to a large distance to improve the dielectric voltage of the transformer chip 80.

For example, the distance D14 between the second coil 46A and the substrate 84 is equal to or greater than the distance D12 between the first coil 45A and the second coil 46A. In the present embodiment, the distance D14 is larger than the distance D12. For example, the distance D14 is equal to or more than double the distance D12. However, the distances are not limited to these, and the distance D14 may be less than double the distance D12.

Further, the distance D14 between the second coil 46A and the substrate 84 is, for example, equal to or greater than the distance D11 between the first coil 43A and the second coil 44A. In the present embodiment, the distance D14 is equal to the distance D11.

It can also be described that the first coil 43A is at a position closer to the substrate 84 than the second coil 46A. Both the first coil 43A and the substrate 84 are electrically connected to the low voltage die pad 91, and the ground of the first coil 43A and the substrate 84 have the same potential. This can suppress the reduction in the dielectric voltage of the transformer chip 80 even when the first coil 43A is arranged near the substrate 84. In the present embodiment, the distance D13 between the first coil 43A and the substrate 84 is smaller than the distance D11 between the first coil 43A and the second coil 44A. The distance D13 is equal to or smaller than ½ the distance D11. However, the distances are not limited to these, and the distance D13 may be larger than ½ the distance D11.

A distance D15 between the second coil 46A and the first coil 43A is, for example, equal to or greater than the distance D14 between the second coil 46A and the substrate 84. The distance D15 is the shortest distance between the second coil 46A and the first coil 43A. In the present embodiment, the distance D15 is equal to the distance D14. The distance D15 is equal to or greater than the distance D11 between the first coil 43A and the second coil 44A. In the present embodiment, the distance D14 is equal to the distance D11, and thus, the distance D15 is equal to the distance D11.

A distance D16 between the second coil 44A and the first coil 45A is set according to the distance D15 between the second coil 46A and the first coil 43A. More specifically, a central axis J1 of the first coil 43A coincides with a central axis J2 of the second coil 44A, and a central axis J3 of the first coil 45A coincides with a central axis J4 of the second coil 46A. Thus, as the distance D15 is set, the positions of the first coil 43A and the second coil 46A in the x direction and the y direction are set. The positions of the second coil 44A and the first coil 45A in the x direction and the y direction are the same as the positions of the first coil 43A and the second coil 46A in the x direction and the y direction in plan view. Accordingly, the distance D16 is set.

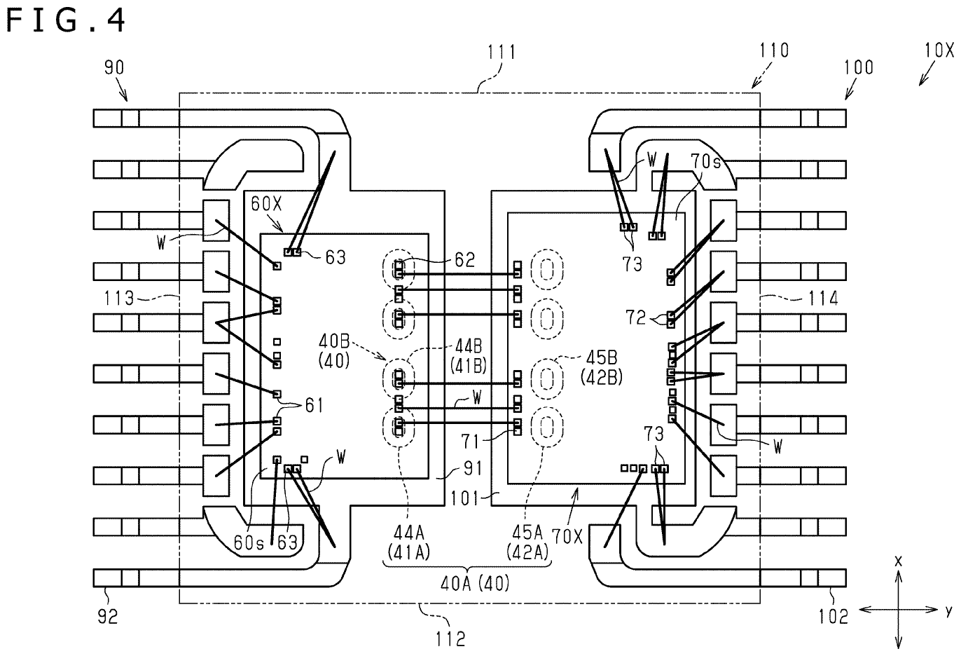

An action of the gate driver 10 in the present embodiment will be described with reference to FIGS. 2 and 4. FIG. 4 illustrates a cross-sectional structure of a transformer chip of a gate driver 10X in a comparison example. Note that, in the description of the gate driver 10X in the comparison example, the same signs are used for the constituent elements common to the gate driver 10.

As illustrated in FIG. 4, in the gate driver 10X of the comparison example, the low voltage circuit chip 60 includes the first transformers 41A and 41B, and the high voltage circuit chip 70 includes the second transformers 42A and 42B. The low voltage circuit 20 and the first transformers 41A and 41B are electrically connected. The high voltage circuit 30 and the second transformers 42A and 42B are electrically connected.

The low voltage circuit chip 60 and the high voltage circuit chip 70 are connected through the wires W. As a result, the second coil 44A of the first transformer 41A and the second coil 46A of the second transformer 42A are electrically connected, and the second coil 44B of the first transformer 41B and the second coil 46B of the second transformer 42B are electrically connected.

In this way, in the gate driver 10X of the comparison example, the first transformers 41A and 41B are included in a low voltage circuit chip 60X, and the second transformers 42A and 42B are included in a high voltage circuit chip 70X. Thus, the low voltage circuit chip 60X and the high voltage circuit chip 70X may need to be changed when the configuration of the low voltage circuit 20 is changed or when the configuration of the high voltage circuit 30 is changed. The low voltage circuit chip 60X and the high voltage circuit chip 70X may need to be changed even when the configuration of the first transformers 41A and 41B and the configuration of the second transformers 42A and 42B are the same.

In this regard, the first transformers 41A and 41B and the second transformers 42A and 42B are included in one transformer chip 80 in the present embodiment. That is, the gate driver 10 includes a chip dedicated to the first transformers 41A and 41B and the second transformers 42A and 42B. Thus, the first transformers 41A and 41B and the second transformers 42A and 42B do not have to be changed when there is a change in configuration of the low voltage circuit 20 or the high voltage circuit 30, unlike in the low voltage circuit chip 60X or the high voltage circuit chip 70X of the gate driver 10X in the comparison example.

According to the gate driver 10 of the present embodiment, the following effects can be obtained. Although the first transformer 41A and the second transformer 42A will be described below, similar effects can also be obtained for the first transformer 41B and the second transformer 42B.

(1-1) The gate driver 10 includes the low voltage circuit 20 that operates when the first voltage V1 is applied; the high voltage circuit 30 that operates when the second voltage V2 higher than the first voltage V1 is applied; and the transformer chip 80. The transformer chip 80 includes the substrate 84; the insulating layer 86 formed on the substrate 84; the first transformer 41A including the first coil 43A and the second coil 44A embedded into the insulating layer 86 and arranged to face each other; and the second transformer 42A including the first coil 45A and the second coil 46A embedded into the insulating layer 86 and arranged to face each other. The low voltage circuit 20 and the high voltage circuit 30 are connected through the first transformer 41A and the second transformer 42A connected in series and are configured to transmit signals through the first transformer 41A and the second transformer 42A.

According to the configuration, the low voltage circuit 20 and the high voltage circuit 30 are connected through the first transformer 41A and the second transformer 42A connected to each other in series and are configured to transmit signals through the transformers 41A and 42A. This can improve the dielectric voltage of the gate driver 10 compared to the configuration of transmitting signals through one transformer.

Here, an example of the configuration in which the gate driver 10 includes two transformers connected to each other in series includes a configuration in which the gate driver 10 includes a first chip including a low voltage circuit and a first transformer; and a second chip including a high voltage circuit and a second transformer. The chips are connected through wires to connect the first transformer and the second transformer in series. However, the chips may need to be changed when the low voltage circuit or the high voltage circuit is changed in the configuration, and this increases the cost of manufacturing a plurality of types of gate drivers.

In this regard, the first transformer 41A and the second transformer 42A are provided in one transformer chip 80 according to the present embodiment. That is, a chip dedicated to the transformers 40 is provided. Thus, a common transformer chip 80 can be used for the low voltage circuit 20 and the high voltage circuit 30 that are different. This can reduce the cost of manufacturing a plurality of types of gate drivers 10 in which at least one of the low voltage circuit 20 and the high voltage circuit 30 is different.

(1-2) The gate driver 10 includes the low voltage die pad 91 provided with the low voltage circuit 20. The transformer chip 80 is mounted on the low voltage die pad 91. The low voltage circuit 20 and the first coil 43A are electrically connected. The high voltage circuit 30 and the second coil 46A are electrically connected. The second coil 44A and the first coil 45A are electrically connected. The first coil 43A is arranged closer to the substrate 84 than the second coil 44A in the z direction. The second coil 46A is arranged closer to the substrate 84 than the first coil 45A in the z direction. The second coil 46A is at a position farther from the substrate 84 than the first coil 43A in the z direction.

According to the configuration, a high voltage is not easily applied to the first coil 43A when the first coil 43A and the substrate 84 are connected to the ground of the low voltage circuit 20. On the other hand, the potential of the second coil 46A tends to be higher than the potential of the substrate 84 when the second coil 44A is connected to the ground of the high voltage circuit 30. Thus, a high voltage is easily applied between the second coil 46A and the substrate 84.

In this regard, the distance D14 between the second coil 46A, to which a high voltage is easily applied, and the substrate 84 is larger than the distance D13 between the first coil 43A, to which a high voltage is not easily applied, and the substrate 84 in the present embodiment. This can improve the dielectric voltage of the transformer chip 80.

(1-3) The distance D14 between the second coil 46A of the second transformer 42A and the substrate 84 is equal to or greater than the distance D11 between the first coil 43A of the first transformer 41A and the second coil 44A. According to the configuration, the distance D14 between the second coil 46A, to which a high voltage is easily applied, and the substrate 84 can be large, and this can improve the dielectric voltage of the transformer chip 80.

(1-4) The distance D14 between the second coil 46A of the second transformer 42A and the substrate 84 is equal to or greater than the distance D12 between the first coil 45A and the second coil 46A of the second transformer 42A. According to the configuration, an increase in the dimension of the transformer chip 80 in the z direction can be suppressed, and the distance D14 between the second coil 46A and the substrate 84 can be large. This can improve the dielectric voltage of the transformer chip 80. In addition, the voltage applied between the first coil 45A and the second coil 46A tends to be lower than that applied between the second coil 46A and the substrate 84. This can secure the dielectric voltage of the transformer chip 80 even when the distance D12 is small.

(1-5) The distance D15 between the second coil 46A of the second transformer 42A and the first coil 43A of the first transformer 41A is equal to or greater than the distance D14 between the second coil 46A and the substrate 84.

When the first transformer 41A and the second transformer 42A are included in one chip, a high voltage is also easily applied between the first coil 43A of the first transformer 41A and the second coil 46A of the second transformer 42A, and a dielectric breakdown easily occurs. In this regard, the distance D15 between the second coil 46A and the first coil 43A is set to a distance equal to or greater than the distance D14 between the second coil 46A and the substrate 84 in the present embodiment, and a dielectric breakdown does not easily occur between the first coil 43A and the second coil 46A. This can improve the dielectric voltage of the transformer chip 80.

(1-6) The distance D11 between the first coil 43A and the second coil 44A of the first transformer 41A is larger than the distance D12 between the first coil 45A and the second coil 46A of the second transformer 42A. The configuration can suppress occurrence of a dielectric breakdown between the first coil 43A and the second coil 44A. This can suppress application of a high voltage to the first coil 43A even if a dielectric breakdown occurs between the first coil 45A and the second coil 46A due to some kind of factor.

(1-7) The second coil 44A of the first transformer 41A and the first coil 45A of the second transformer 42A are in line with each other in the z direction. According to the configuration, both the second coil 44A and the first coil 45A are provided on the same insulating layer 86. Thus, the coils 44A and 45A can be manufactured at the same time, and the manufacturing of the transformer chip 80 can be simplified.

(1-8) The second coil 44A of the first transformer 41A and the first coil 45A of the second transformer 42A are connected through the connection wire 83. According to the configuration, the distance between the second coil 44A and the first coil 45A in the y direction can be smaller than that in the structure of connecting the second coil 44A and the first coil 45A with use of the wire W. Thus, the transformer chip 80 can be downsized.

(1-9) The first transformer 41A and the second transformer 42A are in line with each other in the x direction and separately arrayed in the y direction in plan view. According to the configuration, the transformer chip 80 can be smaller than in the configuration in which the first transformer 41A and the second transformer 42A are arranged not in line with each other in the x direction in plan view.

(1-10) The first transformer 41A is arranged closer to the low voltage circuit chip 60 than the second transformer 42A in the transformer chip 80. According to the configuration, the first transformer 41A electrically connected to the low voltage circuit 20 is arranged near the low voltage circuit chip 60, and the conductive path between the low voltage circuit 20 and the first transformer 41A can be shortened. This can reduce the inductance caused by the length of the conductive path between the low voltage circuit 20 and the first transformer 41A.

The second transformer 42A is arranged closer to the high voltage circuit chip 70 than the first transformer 41A in the transformer chip 80. According to the configuration, the second transformer 42A electrically connected to the high voltage circuit 30 is arranged near the high voltage circuit chip 70, and the conductive path between the high voltage circuit 30 and the second transformer 42A can be shortened. This can reduce the inductance caused by the length of the conductive path between the high voltage circuit 30 and the second transformer 42A.

(1-11) The winding direction of the coils 43A and 44A of the first transformer 41A and the winding direction of the coils 45A and 46A of the second transformer 42A are opposite directions. The configuration can strengthen the magnetic field of the coils 43A and 44A and the magnetic field of the coils 45A and 46A. As a result, the first transformer 41A and the second transformer 42A can be brought close to each other in the y direction. Thus, the transformer chip 80 can be downsized.

### Second Embodiment

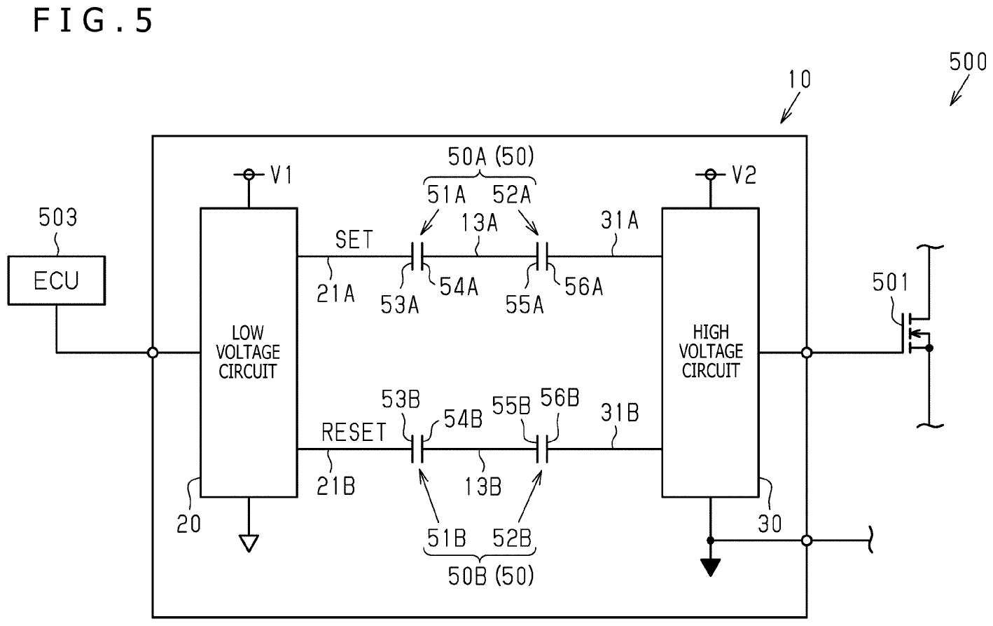

The gate driver 10 of a second embodiment will be described with reference to FIGS. 5 to 7. The gate driver 10 of the present embodiment is different from the gate driver 10 of the first embodiment in that the insulation structure based on the transformers 40 is changed to an insulation structure based on capacitors 50. In the following description, the difference from the first embodiment will mainly be described. The same signs are provided to the constituent elements common to the first embodiment, and the description will not be repeated.

As illustrated in FIG. 5, the capacitors 50 as an insulation structure for electrically insulating the low voltage circuit 20 and the high voltage circuit 30 include a capacitor 50A connected to signal lines for transmitting a set signal; and a capacitor 50B connected to signal lines for transmitting a reset signal. The capacitors 50A and 50B are both provided between the low voltage circuit 20 and the high voltage circuit 30.

In the gate driver 10, the signal lines for transmitting the set signal include a connection signal line 13A provided between the low voltage signal line 21A and the high voltage signal line 31A, and the signal lines for transmitting the reset signal include a connection signal line 13B provided between the low voltage signal line 21B and the high voltage signal line 31B. Thus, the signal lines for transmitting the set signal include the low voltage signal line 21A, the high voltage signal line 31A, and the connection signal line 13A. The signal lines for transmitting the reset signal include the low voltage signal line 21B, the high voltage signal line 31B, and the connection signal line 13B.

The capacitor 50A includes a first capacitor 51A and a second capacitor 52A connected to each other in series through the connection signal line 13A. The first capacitor 51A is electrically connected to the low voltage circuit 20, and the second capacitor 52A is electrically connected to the high voltage circuit 30. More specifically, the first capacitor 51A includes a first electrode 53A and a second electrode 54A, and the second capacitor 52A includes a first electrode 55A and a second electrode 56A. The first electrode 53A of the first capacitor 51A is connected to the low voltage circuit 20 through the low voltage signal line 21A, and the second electrode 54A is connected to the first electrode 55A of the second capacitor 52A through the connection signal line 13A. The second electrode 56A of the second capacitor 52A is connected to the high voltage circuit 30 through the high voltage signal line 31A. Thus, the low voltage circuit 20 and the high voltage circuit 30 transmit the set signal through the first capacitor 51A and the second capacitor 52A connected to each other in series.

The capacitor 50B includes a first capacitor 51B and a second capacitor 52B connected to each other in series through the connection signal line 13B. The first capacitor 51B includes a first electrode 53B and a second electrode 54B, and the second capacitor 52B includes a first electrode 55B and a second electrode 56B. The configuration of the capacitor 50B and the configuration of connection between the low voltage circuit 20 and the high voltage circuit 30 are similar to those of the capacitor 50A, and the detailed description will not be repeated. The low voltage circuit 20 and the high voltage circuit 30 transmit the reset signal through the first capacitor 51B and the second capacitor 52B connected to each other in series.

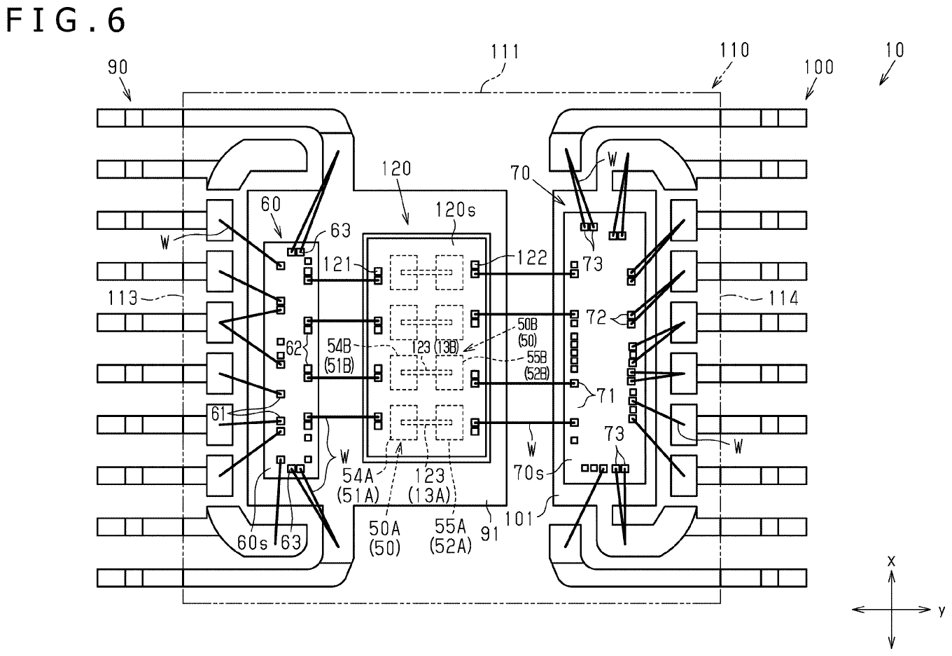

As illustrated in FIG. 6, the gate driver 10 includes a capacitor chip 120 including the capacitors 50A and 50B, in place of the transformer chip 80 of the first embodiment. The arrangement configuration of the capacitor chip 120 in the gate driver 10 is similar to that of the transformer chip 80 in the first embodiment. Thus, the capacitor chip 120 is mounted on the low voltage die pad 91. In the present embodiment, the capacitor chip 120 corresponds to the insulating chip.

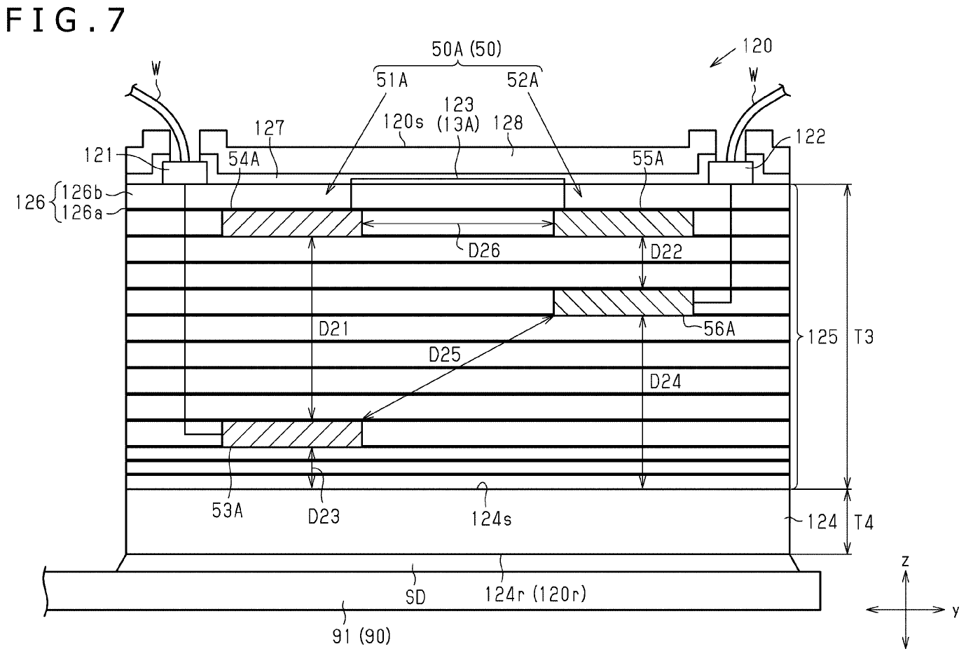

As illustrated in FIG. 7, the capacitor chip 120 includes a chip main surface 120s and a chip back surface 120r facing opposite sides in the z direction. The conductive bonding material SD is used to bond the chip back surface 120r of the capacitor chip 120 to the low voltage die pad 91.

As illustrated in FIG. 6, a plurality of first electrode pads 121 and a plurality of second electrode pads 122 are formed on the chip main surface 120s of the capacitor chip 120. The capacitor chip 120 includes a plurality of connection wires 123. The plurality of first electrode pads 121 are arranged on one of the ends of the chip main surface 120s in the y direction that is closer to the low voltage circuit chip 60. The plurality of first electrode pads 121 are arrayed in the x direction. The plurality of second electrode pads 122 are arranged on one of the ends of the chip main surface 120s in the y direction closer to the high voltage circuit chip 70. The plurality of second electrode pads 122 are arrayed in the x direction. The capacitors 50A and 50B are arrayed between the plurality of first electrode pads 121 and the plurality of second electrode pads 122 in the y direction in plan view. The capacitors 50A and 50B are in line with each other in the y direction and separately arrayed in the x direction. The plurality of connection wires 123 are arranged inside of the ends of the chip main surface 120s in the y direction. The electrode pads 121 and 122 and the connection wire 123 are electrically connected to the capacitors 50A and 50B.

An example of the internal structure of the capacitor chip 120 will be described with reference to FIG. 7. FIG. 7 illustrates a schematic cross-sectional structure of the capacitor 50A. Note that the configuration of the capacitor 50B is the same as the configuration of the capacitor 50A, and the description will not be repeated. In the following description, the direction from the chip back surface 120r toward the chip main surface 120s of the capacitor chip 120 will be referred to as “above,” and the direction from the chip main surface 120s toward the chip back surface 120r will be referred to as “below.”

As illustrated in FIG. 7, the capacitor chip 120 includes both the capacitors 50A and 50B (see FIG. 6), and more specifically, the capacitor chip 120 is provided by forming a chip including both the capacitors 50A and 50B. The capacitor chip 120 includes a substrate 124 and an insulating layer laminated body 125 formed on the substrate 124, similarly to the transformer chip 80 of the first embodiment (see FIG. 3).

The substrate 124 includes, for example, a semiconductor substrate, and the substrate 124 is a substrate formed from a material containing Si in the present embodiment. The substrate 124 includes a substrate main surface 124s and a substrate back surface 124r facing opposite sides in the z direction. The substrate back surface 124r provides the chip back surface 120r of the capacitor chip 120.

The insulating layer laminated body 125 includes a plurality of insulating layers 126 laminated in the z direction, each insulating layer 126 including a first insulating layer 126a and a second insulating layer 126b laminated on the first insulating layer 126a. The insulating layer 126 is formed on the substrate main surface 124s of the substrate 124. In the present embodiment, the insulating layer 126 includes a dielectric layer. The material of the first insulating layer 126a and the second insulating layer 126b may be, for example, the same as the material of the first insulating layer 86a and the second insulating layer 86b of the first embodiment (see FIG. 3). A thickness T3 of the insulating layer laminated body 125 is thicker than a thickness T4 of the substrate 124.

The first capacitor 51A and the second capacitor 52A are embedded into the insulating layer 126. As illustrated in FIGS. 6 and 7, the first capacitor 51A and the second capacitor 52A are in line with each other in the x direction and separately arranged in the y direction. The first capacitor 51A and the second capacitor 52A can also be described as being separately arranged in the array direction of the chips 60, 70, and 120. As illustrated in FIG. 6, the capacitor chip 120 is mounted in a state in which the first capacitor 51A of the capacitor 50A and the first capacitor 51B of the capacitor 50B are arranged closer to the low voltage circuit chip 60 and the second capacitor 52A of the capacitor 50A and the second capacitor 52B of the capacitor 50B are arranged closer to the high voltage circuit chip 70.

As illustrated in FIG. 6, the shapes of the electrodes 54A and 55A of the capacitors 51A and 52A in plan view are rectangular. Although not illustrated, the shapes of the electrodes 53A and 56A of the capacitors 51A and 52A in plan view are similarly rectangular. In the present embodiment, the size of the first electrode 53A of the first capacitor 51A is equal to the size of the second electrode 54A. The size of the first electrode 55A of the second capacitor 52A is equal to the size of the second electrode 56A. As illustrated in FIG. 6, the size of the second electrode 54A is equal to the size of the first electrode 55A in the present embodiment. Note that the sizes of the electrodes 53A, 54A, 55A, and 56A can be any size, and the sizes can be individually changed.

As illustrated in FIG. 7, the first electrode 53A and the second electrode 54A of the first capacitor 51A are arranged to face each other in the z direction through the insulating layer 126. The electrodes 53A and 54A are provided as conductive layers embedded into one insulating layer 126. That is, an opening portion going through both the first insulating layer 126a and the second insulating layer 126b in the z direction is formed on the insulating layer 126 provided with the electrodes 53A and 54A. The conductive layers included in the electrodes 53A and 54A are embedded into the opening portion of the insulating layer 126.

In other words, the first electrode 53A and the second electrode 54A are embedded into the insulating layer laminated body 125 including the plurality of laminated insulating layers 126. That is, the first electrode 53A and the second electrode 54A of the present embodiment can also be described as being separately arranged to face each other through one or a plurality of insulating layers 126 and embedded into the insulating layer laminated body 125 including a plurality of insulating layers 126.

The second electrode 54A is at a position farther from the substrate 124 than the first electrode 53A in the z direction. In other words, the second electrode 54A is positioned above the first electrode 53A. In the present embodiment, the second electrode 54A corresponds to the second conductor of the first insulating element, and the first electrode 53A corresponds to the first conductor of the first insulating element. In addition, the second electrode 54A corresponds to the second electrode plate, and the first electrode 53A corresponds to the first electrode plate.

The first electrode 55A and the second electrode 56A of the second capacitor 52A are arranged to face each other in the z direction through the insulating layer 126. Similarly to the electrodes 53A and 54A, the electrodes 55A and 56A are provided as conductive layers embedded into one insulating layer 126. The first electrode 55A is at a position farther from the substrate 124 than the second electrode 56A in the z direction. In other words, the first electrode 55A is positioned above the second electrode 56A. In the present embodiment, the first electrode 55A corresponds to the fourth conductor of the second insulating element, and the second electrode 56A corresponds to the third conductor of the second insulating element. In addition, the first electrode 55A corresponds to the fourth electrode plate, and the second electrode 56A corresponds to the third electrode plate.

The capacitor chip 120 further includes a protection film 127 formed on the insulating layer laminated body 125 and a passivation film 128 formed on the protection film 127, similarly to the transformer chip 80. The same material as the material of the protection film 87 and the passivation film 88 of the transformer chip 80 (see FIG. 3) is used for the protection film 127 and the passivation film 128. The passivation film 128 provides the chip main surface 120s of the capacitor chip 120.

The plurality of first electrode pads 121, the plurality of second electrode pads 122, and the plurality of connection wires 123 are formed on the insulating layer laminated body 125. Both the protection film 127 and the passivation film 128 are formed to cover the peripheries of the upper surfaces of the pads 121 and 122 and the connection wires 123. Thus, on each of the pads 121 and 122, an exposed surface for connecting the wire W thereto is formed.

The first electrode 53A is electrically connected to the first electrode pad 121 used for establishing electrical connection to the low voltage circuit 20. In this way, the low voltage circuit 20 and the first electrode 53A are electrically connected. The second electrode 54A and the first electrode 55A are connected through the connection wire 123. In this way, the second electrode 54A and the first electrode 55A are electrically connected. The second electrode 56A is electrically connected to the second electrode pad 122 used for establishing electrical connection to the high voltage circuit 30. In this way, the high voltage circuit 30 and the second electrode 56A are electrically connected. Thus, the connection wire 123 connecting the second electrode 54A and the first electrode 55A provides the connection signal line 13A. In this way, the capacitor chip 120 includes the connection wire 123 connecting the first capacitor 51A and the second capacitor 52A in series. In the present embodiment, the connection wire 123 corresponds to the wire.

Next, the positional relation between the first electrodes 53A and 55A and the second electrodes 54A and 56A in the capacitor chip 120 will be described. Note that the positional relation between the first electrodes 53B and 55B and the second electrodes 54B and 56B in the capacitor chip 120 is similar to the positional relation between the first electrodes 53A and 55A and the second electrodes 54A and 56A in the capacitor chip 120, and the description will not be repeated.

The positions of the first electrodes 53A and 55A and the second electrodes 54A and 56A in the capacitor chip 120 are set to bring the dielectric voltage of the capacitor chip 120 into line with the preset dielectric voltage.

A distance D21 between the first electrode 53A and the second electrode 54A is larger than a distance D22 between the first electrode 55A and the second electrode 56B. In the present embodiment, the distance D21 is equal to or more than double the distance D22. However, the distances are not limited to these, and the distance D21 may be less than double the distance D22.

In the present embodiment, the second electrode 54A and the first electrode 55A are in line with each other in the z direction. On the other hand, the second electrode 56A is at a position farther from the substrate 124 than the first electrode 53A in the z direction (that is, above the first electrode 53A). As a result, the distance D21 is larger than the distance D22.

In this case, the second electrode 56A is arranged at a position between the first electrode 53A and the second electrode 54A in the z direction as viewed from the y direction. That is, a distance D24 between the second electrode 56A and the substrate 124 is larger than a distance D23 between the first electrode 53A and the substrate 124. In the present embodiment, the distance D24 is equal to or more than double the distance D23. However, the distances are not limited to these, and the distance D24 may be less than double the distance D23.

The second electrode 56A is electrically connected to the high voltage die pad 101, and the substrate 124 is electrically connected to the low voltage die pad 91. Thus, the potential of the ground of the second electrode 56A and the potential of the substrate 124 may be different. Accordingly, the second electrode 56A and the substrate 124 may need to be insulated. That is, the distance D24 between the second electrode 56A and the substrate 124 can be set to a large distance to improve the dielectric voltage of the capacitor chip 120.

It can also be described that the first electrode 53A is at a position closer to the substrate 124 than the second electrode 54A. Both the first electrode 53A and the substrate 124 are electrically connected to the low voltage die pad 91, and the ground of the first electrode 53A and the substrate 124 have the same potential. This can suppress the reduction in the dielectric voltage of the capacitor chip 120 even when the first electrode 53A is arranged near the substrate 124. In the present embodiment, the distance D23 between the first electrode 53A and the substrate 124 is smaller than the distance D21 between the first electrode 53A and the second electrode 54A. The distance D23 may be equal to or smaller than ½ the distance D21. However, the distances are not limited to these, and the distance D23 may be larger than ½ the distance D21.

For example, the distance D24 between the second electrode 56A and the substrate 124 is equal to or greater than the distance D22 between the first electrode 55A and the second electrode 56A. In the present embodiment, the distance D24 is larger than the distance D22. The distance D24 may be equal to or more than double the distance D22. However, the distances are not limited to these, and the distance D24 may be less than double the distance D22.

The distance D24 between the second electrode 56A and the substrate 124 is, for example, equal to or greater than the distance D21 between the first electrode 53A and the second electrode 54A. In the present embodiment, the distance D24 is equal to the distance D21.

A distance D25 between the second electrode 56A and the first electrode 53A is, for example, equal to or greater than the distance D24 between the second electrode 56A and the substrate 124. In the present embodiment, the distance D25 is equal to the distance D24. The distance D25 is equal to or greater than the distance D21 between the first electrode 53A and the second electrode 54A. In the present embodiment, the distance D24 is equal to the distance D21, and thus, the distance D25 is equal to the distance D21.

A distance D26 between the second electrode 54A and the first electrode 55A is set according to the distance D25 between the second electrode 56A and the first electrode 53A. More specifically, the center of the first electrode 53A coincides with the center of the second electrode 54A, and the center of the first electrode 55A coincides with the center of the second electrode 56A. Thus, as the distance D25 is set, the positions of the first electrode 53A and the second electrode 56A in the x direction and the y direction are set. The positions of the second electrode 54A and the first electrode 55A in the x direction and the y direction are the same as the positions of the first electrode 53A and the second electrode 56A in the x direction and the y direction in plan view. Thus, the distance D26 is set. According to the gate driver 10 of the present embodiment, effects similar to the effects of the gate driver 10 in the first embodiment can be obtained.

### Modification Examples

The abovementioned embodiments illustrate possible modes of the gate driver related to the present disclosure, but are not intended to limit the modes. The gate driver related to an embodiment of the present disclosure can have modes different from the modes illustrated in the embodiments. Examples of the modes include modes in which part of the configurations of the embodiments is replaced, changed, or omitted, as well as modes in which new configurations are added to the embodiments. The following modification examples can be combined with each other as long as there is no technical contradiction. In the following modification examples, the same signs as the signs in the embodiments are provided to the parts common to the embodiments, and the description will not be repeated.

The configuration and the material of the substrate 84 can be changed to any configuration and material in the first embodiment.

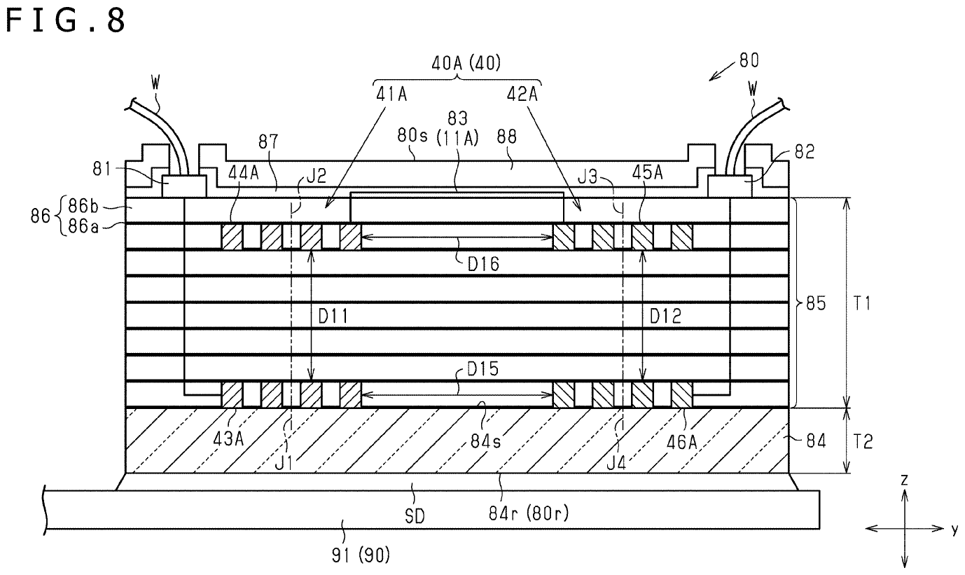

In a first example, the substrate 84 may be a substrate formed from a material containing glass as illustrated in FIG. 8. In this case, the substrate 84 is electrically insulating, and a high voltage is not easily applied between the second coil 46A of the second transformer 42A and the substrate 84. Thus, the second coil 46A can be brought close to the substrate 84. In an example, the position of the second coil 46A in the z direction is in line with the position of the first coil 43A of the first transformer 41A in the z direction. In other words, the first coil 43A and the second coil 46A are arranged at positions in line with each other in the z direction. That is, the second coil 46A and the first coil 43A are provided on the same insulating layer 86 among the plurality of insulating layers 86. In the illustrated example, the second coil 46A and the first coil 43A are provided on the lowermost insulating layer 86 among the plurality of insulating layers 86.

The second coil 44A and the first coil 45A are arranged at positions in line with each other in the z direction, and thus, the distance D11 between the first coil 43A and the second coil 44A is equal to the distance D12 between the first coil 45A and the second coil 46A. In the illustrated example, the distance D15 between the first coil 43A and the second coil 46A is equal to or greater than the distance D11 and the distance D12. In the illustrated example, the distance D15 is larger than the distance D11 and the distance D12. In the illustrated example, the distance D15 is equal to the distance D16 between the second coil 44A and the first coil 45A.

According to the configuration, the substrate 84 is a substrate formed from a material containing glass, and thus, a high voltage is not easily applied between the second coil 46A and the substrate 84. As a result, the dielectric voltage of the transformer chip 80 is set on the basis of the dielectric voltage between the first coil 43A and the second coil 46A. Thus, the dielectric voltage of the transformer chip 80 can easily be set.

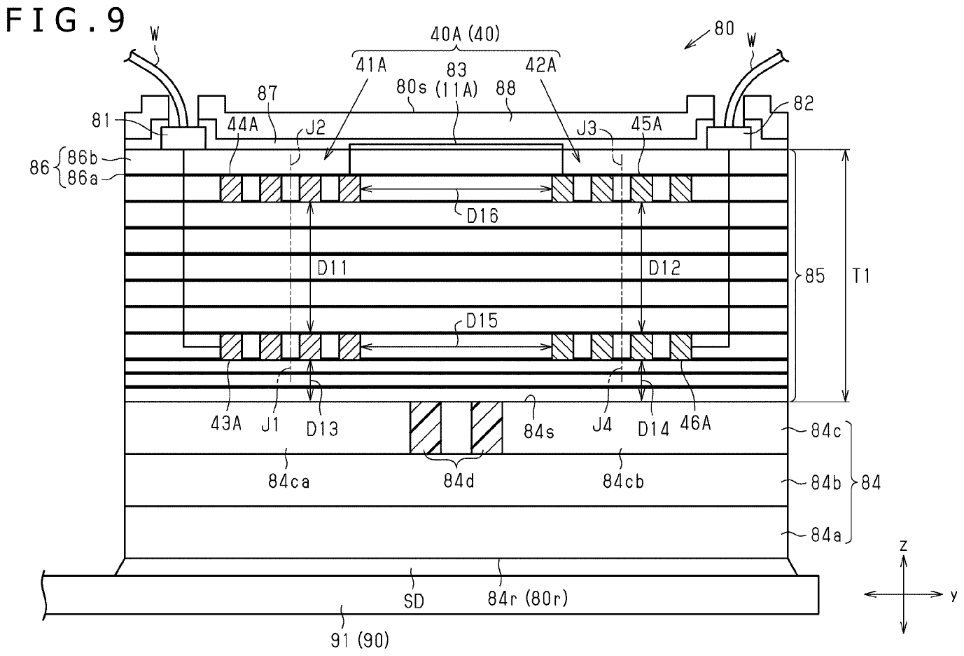

In a second example, the substrate 84 may be a silicon on insulator (SOI) substrate as illustrated in FIG. 9. The substrate 84 includes a lower Si layer 84a, an SiO₂ layer 84b as an insulating layer laminated on the lower Si layer 84a, and an upper Si layer 84c laminated on the SiO₂ layer 84b. It can also be described that the SiO₂ layer 84b is arranged between the lower Si layer 84a and the upper Si layer 84c. Here, the lower Si layer 84a corresponds to the first semiconductor layer. The upper Si layer 84c corresponds to the second semiconductor layer. The SiO₂ layer 84b corresponds to the semiconductor oxide layer.

The lower surface of the lower Si layer 84a provides the chip back surface 80r of the transformer chip 80. In the illustrated example, the SiO₂ layer 84b is laminated over the entire upper surface of the lower Si layer 84a. The upper Si layer 84c is laminated over the entire upper surface of the SiO₂ layer 84b.

A dividing band 84d that contains an insulating material and that goes through the upper Si layer 84c to reach the SiO₂ layer 84b is formed on the upper Si layer 84c. That is, the dividing band 84d is in contact with the SiO₂ layer 84b. The dividing band 84d is, for example, deep trench isolation (DTI). One or a plurality of dividing bands 84d are provided. In the illustrated example, two dividing bands 84d are separately provided in the y direction. The two dividing bands 84d are arranged between the first coil 43A that is a first lower conductor and the second coil 46A that is a second lower conductor in plan view. The two dividing bands 84d divide the upper Si layer 84c into a first Si layer 84ca facing the first coil 43A and a second Si layer 84cb facing the second coil 46A. Here, the first Si layer 84ca corresponds to the first divided semiconductor layer, and the second Si layer 84cb corresponds to the second divided semiconductor layer.

The SiO₂ layer 84b insulates the upper Si layer 84c from the lower Si layer 84a, and the dividing bands 84d insulate the first Si layer 84ca and the second Si layer 84cb. Thus, the second coil 46A can be arranged near the substrate 84 (upper Si layer 84c) in the z direction. In the illustrated example, the second coil 46A and the first coil 43A are arranged at positions in line with each other in the z direction.

The second coil 44A and the first coil 45A are arranged at positions in line with each other in the z direction, and thus, the distance D11 between the first coil 43A and the second coil 44A is equal to the distance D12 between the first coil 45A and the second coil 46A. The distance D13 between the first coil 43A and the substrate 84 (upper Si layer 84c) is equal to the distance D14 between the second coil 46A and the substrate 84 (upper Si layer 84c). In the illustrated example, the distance D15 between the first coil 43A and the second coil 46A is larger than the distance D13 and the distance D14. The distance D15 is equal to or greater than the distance D11 and the distance D12. In the illustrated example, the distance D15 is larger than the distance D11 and the distance D12. In the illustrated example, the distance D15 is equal to the distance D16 between the second coil 44A and the first coil 45A.

According to the configuration, the distance D12 between the first coil 45A and the second coil 46A of the second transformer 42A can be large, and this can improve the dielectric voltage of the transformer chip 80.

The configuration of the substrate 84 illustrated in FIGS. 8 and 9 can also be applied to the substrate 124 of the capacitor chip 120 in the second embodiment. In this case, the positional relation between the first electrode 53A and the second electrode 54A of the first capacitor 51A and the first electrode 55A and the second electrode 56A of the second capacitor 52A is similar to the positional relation between the first coil 43A and the second coil 44A of the first transformer 41A and the first coil 45A and the second coil 46A of the second transformer 42A illustrated in FIGS. 8 and 9.

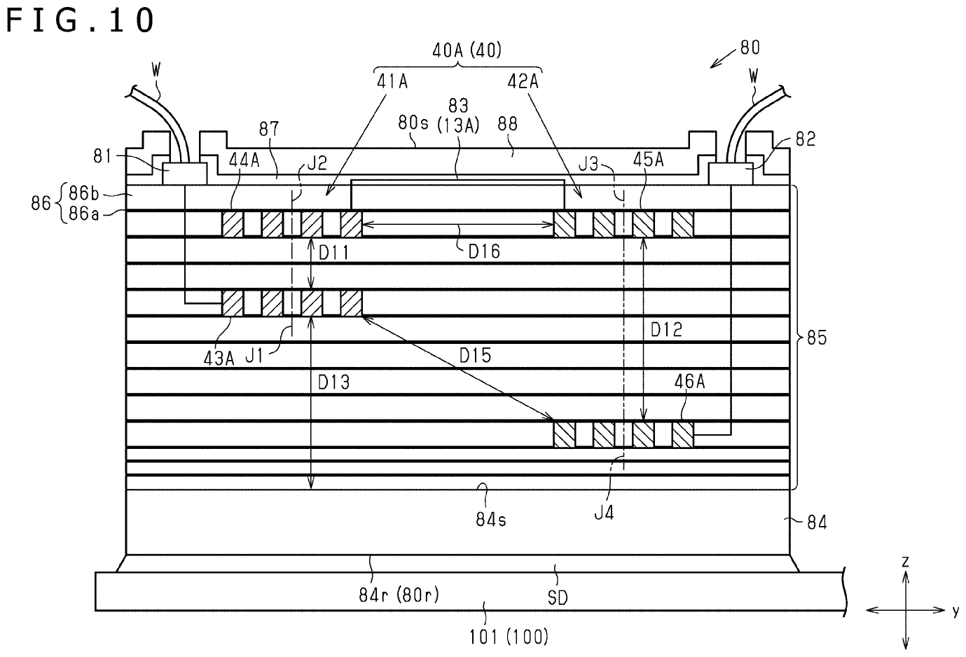

In the first embodiment, the transformer chip 80 may be mounted on the high voltage die pad 101. FIG. 10 illustrates a schematic cross-sectional structure of the transformer chip 80 mounted on the high voltage die pad 101.

As illustrated in FIG. 10, the first coil 43A is electrically connected to the low voltage circuit 20 through the first electrode pad 81, and the second coil 46A is electrically connected to the high voltage circuit 30 through the second electrode pad 82 in the transformer chip 80 of a modification example, as in the first embodiment. The second coil 44A and the first coil 45A are electrically connected through the connection wire 83.

On the other hand, the positional relation between the first coil 43A and the second coil 44A of the first transformer 41A and the first coil 45A and the second coil 46A of the second transformer 42A is different in the transformer chip 80 of the modification example as illustrated in FIG. 10. More specifically, the first coil 43A is at a position farther from the substrate 84 than the second coil 46A in the z direction. The first coil 43A can also be described as being arranged at a position between the first coil 45A and the second coil 46A in the z direction as viewed from the y direction. The second coil 44A and the first coil 45A are in line with each other in the z direction. Thus, the distance D12 between the first coil 45A and the second coil 46A is larger than the distance D11 between the first coil 43A and the second coil 44A. The distance D13 between the first coil 43A and the substrate 84 is larger than the distance D14 between the second coil 46A and the substrate 84.

The distance D13 between the first coil 43A and the substrate 84 is equal to or greater than the distance D11 between the first coil 43A and the second coil 44A. In the illustrated example, the distance D13 is larger than the distance D11.

The distance D13 between the first coil 43A and the substrate 84 is equal to or greater than the distance D12 between the first coil 45A and the second coil 46A. In the illustrated example, the distance D13 is equal to the distance D12.

The distance D15 between the first coil 43A and the second coil 46A is equal to or greater than the distance D13 between the first coil 43A and the substrate 84. In the illustrated example, the distance D15 is equal to the distance D13.

The distance D15 between the first coil 43A and the second coil 46A is equal to or greater than the distance D12 between the first coil 45A and the second coil 46A. In the illustrated example, the distance D15 is equal to the distance D12.

According to the configuration, effects similar to the effects of the gate driver 10 in the first embodiment can be obtained.

Note that the capacitor chip 120 may be mounted on the high voltage die pad 101 in the second embodiment. In this case, the positional relation between the first electrode 53A and the second electrode 54A of the first capacitor 51A and the first electrode 55A and the second electrode 56A of the second capacitor 52A is similar to the positional relation between the first coil 43A and the second coil 44A of the first transformer 41A and the first coil 45A and the second coil 46A of the second transformer 42A illustrated in FIG. 10.

In the first embodiment, the positions of the second coil 44A of the first transformer 41A and the first coil 45A of the second transformer 42A in the z direction can be changed to any position. The positions of the second coil 44A and the first coil 45A in the z direction may be different. For example, the second coil 44A may be positioned below the first coil 45A. Note that the second embodiment may be similarly changed.

In the first embodiment, the distance D11 between the first coil 43A and the second coil 44A may be equal to or smaller than the distance D12 between the first coil 45A and the second coil 46A. In this case, the distance D13 between the first coil 43A and the substrate 84 may be equal to or greater than the distance D14 between the second coil 46A and the substrate 84. Note that the second embodiment may be similarly changed.

In the first embodiment, the distance D14 between the second coil 46A and the substrate 84 may be equal to or smaller than the distance D13 between the first coil 43A and the substrate 84. That is, the second coil 46A may be in line with the first coil 43A in the z direction or may be arranged closer to the substrate 84 than the first coil 43A. In this case, the distance D13 between the first coil 43A and the substrate 84 is preferably equal to or greater than the distance D14 between the second coil 46A and the substrate 84 in the first embodiment. Note that the second embodiment may be similarly changed.

In the first embodiment, the distance D15 between the second coil 46A and the first coil 43A may be smaller than the distance D14 between the second coil 46A and the substrate 84. The distance D15 between the second coil 46A and the first coil 43A may be smaller than the distance D11 between the first coil 43A and the second coil 44A. Note that the second embodiment may be similarly changed.

In the first embodiment, the number of turns of the first coil 43A and the number of turns of the second coil 44A can each be changed to any number. The number of turns of the first coil 45A and the number of turns of the second coil 46A can each be changed to any number. For example, the number of turns of the second coil 44A may be greater than the number of turns of the first coil 43A. The number of turns of the first coil 45A may be greater than the number of turns of the second coil 46A. In this way, the number of turns of the second coil may be greater than the number of turns of the first coil in the first transformer, and the number of turns of the fourth coil may be greater than the number of turns of the third coil in the second transformer.

In the first embodiment, dummy patterns may be provided around the second coils 44A and 44B of the first transformers 41A and 41B. This can suppress the electric field concentration in the second coils 44A and 44B. Dummy patterns may be provided around the second coils 46A and 46B of the second transformers 42A and 42B. This can suppress the electric field concentration in the second coils 46A and 46B.

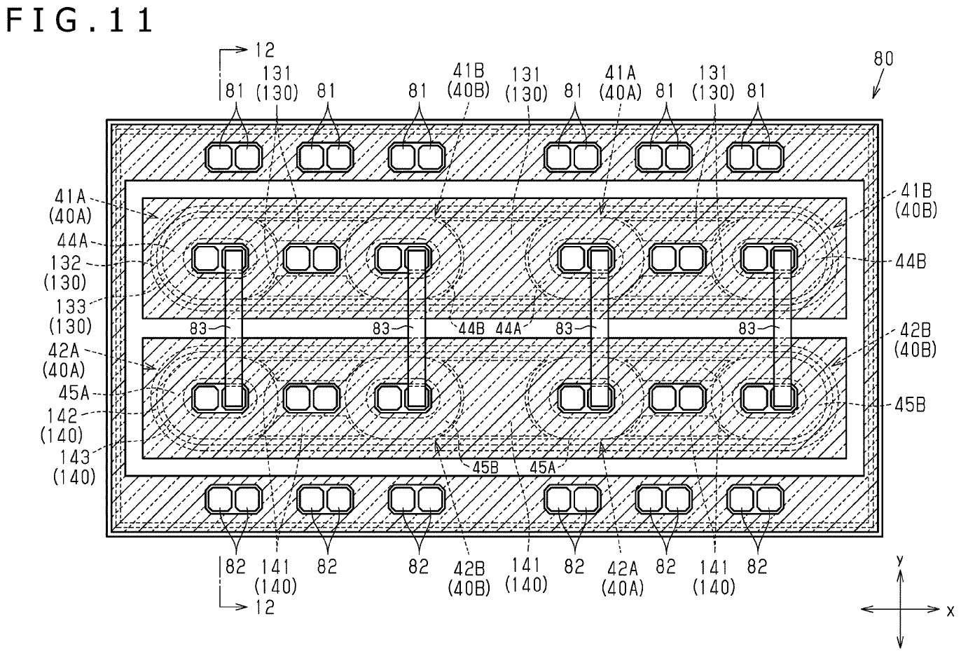

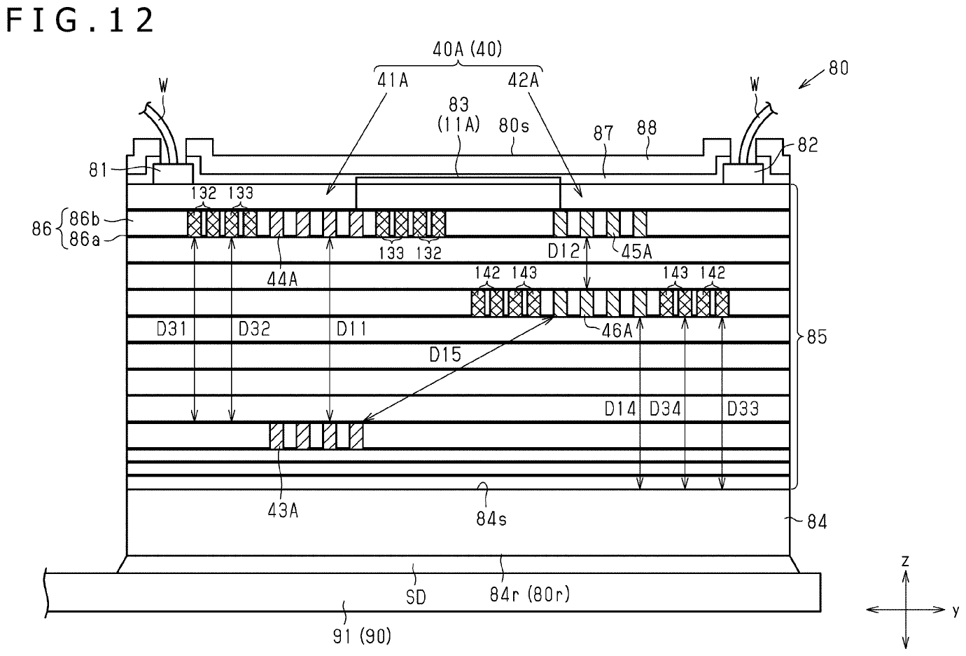

FIGS. 11 and 12 illustrate an example of such dummy patterns. FIG. 11 is a schematic plan view of the transformer chip 80 in which the first transformers 41A and 41B, the second transformers 42A and 42B, and dummy patterns 130 and 140 are indicated by dashed lines. FIG. 12 is a schematic cross-sectional view of the transformer chip 80, illustrating a cross-sectional structure of the first transformer 41A and the second transformer 42A. In the example of FIG. 11, two sets of first transformers 41A and 41B and two sets of second transformers 42A and 42B are provided for the convenience of description. Thus, one set of first transformers 41A and 41B and one set of second transformers 42A and 42B will be described below, and the other set of first transformers 41A and 41B and the other set of second transformers 42A and 42B will not be described.

As illustrated in FIG. 11, the dummy patterns 130 are dummy patterns provided on the first transformers 41A and 41B. The dummy patterns 130 include a first dummy pattern 131, a second dummy pattern 132, and a third dummy pattern 133. Each of the dummy patterns 131 to 133 may contain at least one of Ti (titanium), TiN (titanium nitride), Au, Ag, Cu, Al, and W (tungsten). The dummy patterns 130 here correspond to the first transformer dummy pattern.

The first dummy pattern 131 is formed around each of the second coils 44A and the second coils 44B of the first transformers 41A and 41B as viewed from the z direction. In the illustrated example, the first dummy pattern 131 is formed in a region between the second coil 44A and the second coil 44B adjacent to each other in the x direction.

The first dummy pattern 131 is independent of the second coils 44A and 44B. That is, the first dummy pattern 131 is not electrically connected to the second coils 44A and 44B. Although not illustrated, the first dummy pattern 131 is formed in a pattern different from that of the second coils 44A and 44B.

Although not illustrated, the first dummy pattern 131 is arranged at a position in line with the second coil 44A in the z direction. Although not illustrated, the second coil 44B is arranged at a position in line with the second coil 44A in the z direction, and thus, the first dummy pattern 131 is arranged at a position in line with the second coil 44B in the z direction. That is, the first dummy pattern 131 is arranged at a position farther from the substrate 84 than the first coils 43A and 43B.

A voltage higher than the voltage applied to the first coils 43A and 43B, such as the same voltage as the voltage applied to the second coils 44A and 44B, can be applied to the first dummy pattern 131 to suppress the voltage drop between the second coils 44A and 44B and the first dummy pattern 131. This can suppress the electric field concentration in the second coils 44A and 44B.

The second dummy pattern 132 is formed to surround two second coils 44A and two second coils 44B as viewed from the z direction. The second dummy pattern 132 is formed in an electrically floating state.

As illustrated in FIG. 12, the second dummy pattern 132 is arranged at a position in line with the second coil 44A in the z direction. Although not illustrated, the second dummy pattern 132 is arranged at a position in line with the second coil 44B in the z direction. That is, the second dummy pattern 132 is arranged at a position farther from the substrate 84 than the first coils 43A and 43B.

A voltage higher than the voltage applied to the first coils 43A and 43B, such as the same voltage as the voltage applied to the second coils 44A and 44B, can be applied to the second dummy pattern 132 to suppress the electric field concentration in the second coils 44A and 44B. The second dummy pattern 132 can also suppress the increase in electric field intensity around the second coils 44A and 44B and can suppress the electric field concentration in the connection wire 83.

As illustrated in FIG. 11, the third dummy pattern 133 is formed in a region between the second coils 44A and 44B and the second dummy pattern 132 as viewed from the z direction. The third dummy pattern 133 is formed to surround two second coils 44A and two second coils 44B as viewed from the z direction. The third dummy pattern 133 is independent of the second coils 44A and 44B. That is, the third dummy pattern 133 is not electrically connected to the second coils 44A and 44B.

As illustrated in FIG. 12, the third dummy pattern 133 is arranged at a position in line with the second coil 44A in the z direction. Although not illustrated, the third dummy pattern 133 is arranged at a position in line with the second coil 44B in the z direction. In this way, the dummy patterns 131 to 133 are arranged at positions in line with each other in the z direction. That is, the third dummy pattern 133 is arranged at a position farther from the substrate 84 than the first coils 43A and 43B.

A voltage higher than the voltage applied to the first coils 43A and 43B, such as the same voltage as the voltage applied to the second coils 44A and 44B, can be applied to the third dummy pattern 133 to suppress the voltage drop between the second coils 44A and 44B and the third dummy pattern 133. This can suppress the electric field concentration in the second coils 44A and 44B.

As illustrated in FIG. 11, the dummy patterns 140 are dummy patterns provided on the second transformers 42A and 42B. The dummy patterns 140 are arranged separately from the dummy patterns 130 in the y direction. That is, the insulating layer 86 (see FIG. 12) is present between the dummy patterns 140 and the dummy patterns 130.

The dummy patterns 140 include a first dummy pattern 141, a second dummy pattern 142, and a third dummy pattern 143. The dummy patterns 141 to 143 are formed by the same material as the material of the dummy patterns 131 to 133. The dummy patterns 140 here correspond to the second transformer dummy pattern.

The first dummy pattern 141 is formed around each of the second coil 46A and the second coil 46B of the second transformers 42A and 42B as viewed from the z direction. In the illustrated example, the first dummy pattern 141 is formed in a region between the first coil 45A and the first coil 45B that are adjacent to each other in the x direction.

The first dummy pattern 141 is independent of the second coils 46A and 46B. That is, the first dummy pattern 141 is not electrically connected to the second coils 46A and 46B. Although not illustrated, the first dummy pattern 141 is formed in a pattern different from that of the second coils 46A and 46B.

Although not illustrated, the first dummy pattern 141 is arranged at a position in line with the second coil 46A in the z direction. Although not illustrated, the second coil 46B is arranged at a position in line with the second coil 46A in the z direction, and thus, the first dummy pattern 141 is arranged at a position in line with the second coil 46B in the z direction. That is, the first dummy pattern 141 is arranged closer to the substrate 84 than the first coils 45A and 45B.

A voltage higher than the voltage applied to the first coils 45A and 45B, such as the same voltage as the voltage applied to the second coils 46A and 46B, can be applied to the first dummy pattern 141 to suppress the voltage drop between the second coils 46A and 46B and the first dummy pattern 141. This can suppress the electric field concentration in the second coils 46A and 46B.

As illustrated in FIG. 12, the second dummy pattern 142 is formed to surround two second coils 46A and two second coils 46B as viewed from the z direction. The second dummy pattern 142 is formed in an electrically floating state. As illustrated in FIG. 11, the shape of the second dummy pattern 142 is the same as the shape of the second dummy pattern 132 of the first transformers 41A and 41B.

As illustrated in FIG. 12, the second dummy pattern 142 is arranged at a position in line with the second coil 46A in the z direction. Although not illustrated, the second dummy pattern 142 is arranged at a position in line with the second coil 46B in the z direction. That is, the second dummy pattern 142 is arranged closer to the substrate 84 than the first coils 45A and 45B.

A voltage higher than the voltage applied to the first coils 45A and 45B, such as the same voltage as the voltage applied to the second coils 46A and 46B, can be applied to the second dummy pattern 142 to suppress the electric field concentration in the second coils 46A and 46B. The second dummy pattern 142 can also suppress the increase in electric field intensity around the second coils 46A and 46B and can suppress the electric field concentration in the connection wire 83.

The third dummy pattern 143 is formed in a region between the second coils 46A and 46B and the second dummy pattern 142 in the z direction. The third dummy pattern 143 is formed to surround two second coils 46A and two second coils 46B as viewed from the z direction. As illustrated in FIG. 11, the shape of the third dummy pattern 143 is the same as the shape of the third dummy pattern 133 of the first transformers 41A and 41B. The third dummy pattern 143 is independent of the first coils 45A and 45B. That is, the third dummy pattern 143 is not electrically connected to the first coils 45A and 45B.

As illustrated in FIG. 12, the third dummy pattern 143 is arranged at a position in line with the second coil 46A in the z direction. Although not illustrated, the third dummy pattern 143 is arranged at a position in line with the second coil 46B in the z direction. In this way, the dummy patterns 141 to 143 are arranged at positions in line with each other in the z direction. That is, the third dummy pattern 143 is arranged closer to the substrate 84 than the first coils 45A and 45B. As illustrated in FIG. 12, the second coils 46A and 46B are arranged at positions closer to the substrate 84 than the second coils 44A and 44B in the z direction, and thus, the dummy patterns 141 to 143 are arranged closer to the substrate 84 than the dummy patterns 131 to 133 in the z direction.

A voltage higher than the voltage applied to the first coils 45A and 45B, such as the same voltage as the voltage applied to the second coils 46A and 46B, can be applied to the third dummy pattern 143 to suppress the voltage drop between the second coils 46A and 46B and the third dummy pattern 143. This can suppress the electric field concentration in the second coils 46A and 46B.

Next, the positional relation between the dummy patterns 130 and 140 and the first coil 43A and second coil 46A will be described. Note that the positional relation between the dummy patterns 130 and 140 and the first coil 43A and second coil 46B is similar to the positional relation between the dummy patterns 130 and 140 and the first coil 43A and second coil 46A, and the description will not be repeated.

Although not illustrated, the distance between the first dummy pattern 131 and the first coil 43A in the z direction is larger than the distance D12 (see FIG. 12) between the first coil 45A and the second coil 46A. As illustrated in FIG. 12, a distance D31 between the second dummy pattern 132 and the first coil 43A in the z direction is larger than the distance D12 between the first coil 45A and the second coil 46A. A distance D32 between the third dummy pattern 133 and the first coil 43A in the z direction is larger than the distance D12 between the first coil 45A and the second coil 46A. It can also be described that the dummy patterns 131 to 133 are arranged at positions in line with the first coil 45A in the z direction.

The dummy patterns 141 to 143 are arranged at positions farther from the substrate 84 than the first coil 43A in the z direction. It can also be described that the dummy patterns 141 to 143 are arranged between the first coil 43A and the second coil 44A in the z direction.

Although not illustrated, the distance between the first dummy pattern 141 and the substrate 84 in the z direction is equal to or greater than the distance D11 (see FIG. 12) between the first coil 43A and the second coil 44A in the z direction. The distance D15 (see FIG. 12) between the first coil 43A and the second coil 46A is equal to or greater than the distance between the first dummy pattern 141 and the substrate 84 in the z direction. For example, the distance D15 is equal to the distance between the first dummy pattern 141 and the substrate 84 in the z direction.

As illustrated in FIG. 12, a distance D33 between the second dummy pattern 142 and the substrate 84 in the z direction is equal to or greater than the distance D12 between the first coil 45A and the second coil 46A in the z direction. In the illustrated example, the distance D33 is larger than the distance D12. The distance D15 between the first coil 43A and the second coil 46A is equal to or greater than the distance D33 between the second dummy pattern 142 and the substrate 84 in the z direction. In the illustrated example, the distance D15 is equal to the distance D33.

A distance D34 between the third dummy pattern 143 and the substrate 84 in the z direction is equal to or greater than the distance D12. In the illustrated example, the distance D34 is larger than the distance D12. The distance D15 between the first coil 43A and the second coil 46A is equal to or greater than the distance D34 between the third dummy pattern 143 and the substrate 84 in the z direction. In the illustrated example, the distance D15 is equal to the distance D34.

In the modification example illustrated in FIGS. 11 and 12, one or two of the first dummy pattern 131, the second dummy pattern 132, and the third dummy pattern 133 may be omitted from the dummy patterns 130. One or two of the first dummy pattern 141, the second dummy pattern 142, and the third dummy pattern 143 may also be omitted from the dummy patterns 140.

In the modification example illustrated in FIGS. 11 and 12, dummy patterns similar to the dummy patterns 130 and 140 may be provided on the first coils 45A and 45B of the second transformers 42A and 42B. That is, the dummy patterns may be provided on both the first coils 45A and 45B and the second coils 46A and 46B in the second transformers 42A and 42B.

Although a plurality of insulating layers 86 (126) are formed on the substrate 84 (124) in the embodiments, the configuration is not limited to this. For example, one insulating layer 86 (126) may be formed on the substrate 84 (124). In this case, the thickness of the insulating layer 86 (126) is thicker than the thickness of the insulating layers 86 (126) of the embodiments.

In the first embodiment, the gate driver 10 may include an insulating module including the transformers 40 housed in one package. The insulating module includes the transformer chip 80 and a die pad provided with the transformer chip 80. The insulating module may further include a plurality of leads; wires connecting the plurality of leads and the transformer chip 80; and a sealing resin that seals at least the transformer chip 80, the die pad, and the wires. The plurality of leads can be electrically connected to both the low voltage circuit 20 and the high voltage circuit 30. Note that the gate driver 10 may similarly include an insulating module including the capacitors 50 housed in one package in the second embodiment. That is, the insulating module includes an insulating chip and a die pad provided with the insulating chip. The insulating module is used to insulate the low voltage circuit 20 and the high voltage circuit 30 included in the gate driver 10.

In the first embodiment, the gate driver 10 may include a low voltage circuit unit including the low voltage circuit 20 and the transformers 40 housed in one package. The low voltage circuit unit may include the low voltage circuit chip 60, the transformer chip 80, and a die pad provided with the low voltage circuit chip 60 and the transformer chip 80. The low voltage circuit unit may further include a plurality of first leads; first wires connecting the plurality of first leads and the low voltage circuit chip 60; a plurality of second leads; second wires connecting the plurality of second leads and the transformer chip 80; and a sealing resin that seals at least the low voltage circuit chip 60, the transformer chip 80, the die pad, and the wires. The plurality of first leads can be electrically connected to, for example, the ECU 503, and the plurality of second leads can be electrically connected to the high voltage circuit 30. Note that, in the second embodiment, the gate driver 10 may similarly include a low voltage circuit unit including the low voltage circuit 20 and the capacitors 50 housed in one package. That is, the low voltage circuit unit includes the low voltage circuit 20, an insulating chip, and a die pad provided with the low voltage circuit chip 60 and the insulating chip. In other words, the low voltage circuit unit includes the low voltage circuit 20 and an insulating module.

In the first embodiment, the gate driver 10 may include a high voltage circuit unit including the high voltage circuit 30 and the transformers 40 housed in one package. The high voltage circuit unit may include the high voltage circuit chip 70, the transformer chip 80, and a die pad provided with the high voltage circuit chip 70 and the transformer chip 80. The high voltage circuit unit may further include a plurality of first leads; first wires connecting the plurality of first leads and the high voltage circuit chip 70; a plurality of second leads; second wires connecting the plurality of second leads and the transformer chip 80; and a sealing resin that seals at least the high voltage circuit chip 70, the transformer chip 80, the die pad, and the wires. The plurality of first leads can be electrically connected to, for example, the source of the switching element 501, and the plurality of second leads can be electrically connected to the low voltage circuit 20. Note that, in the second embodiment, the gate driver 10 may similarly include a high voltage circuit unit including the high voltage circuit 30 and the capacitors 50 housed in one package. That is, the high voltage circuit unit includes the high voltage circuit chip 70, an insulating chip, and a die pad provided with the high voltage circuit chip 70 and the insulating chip. In other words, the high voltage circuit unit includes the high voltage circuit 30 and an insulating module.

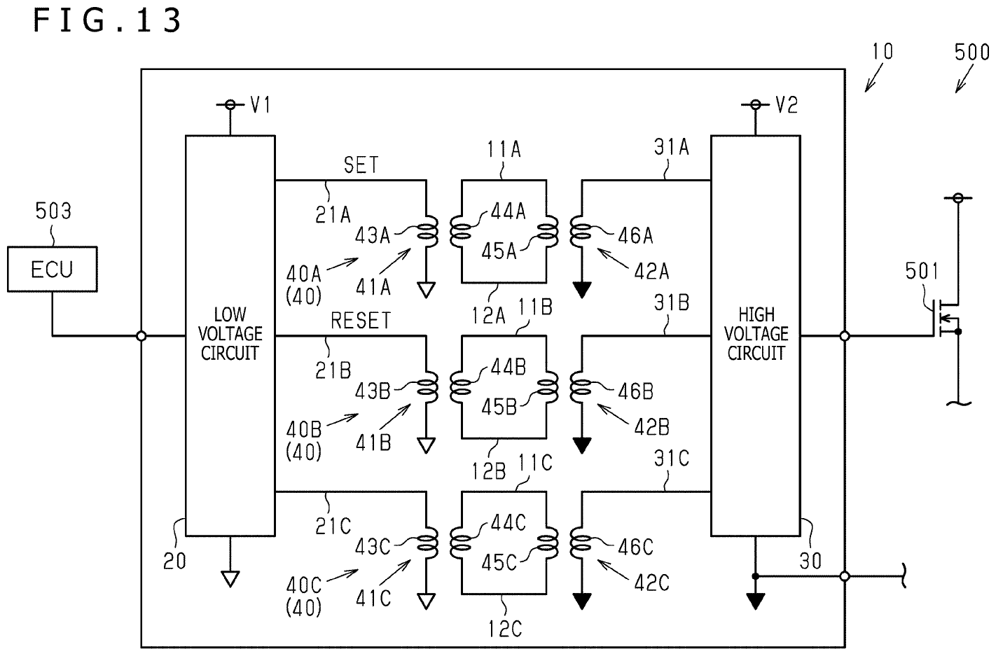

In the embodiments, the gate driver 10 may transmit a signal from the high voltage circuit 30 to the low voltage circuit 20 through a first insulating element and a second insulating element. In an example described below, a signal path for transmitting a signal from the high voltage circuit 30 to the low voltage circuit 20 is added to the gate driver 10 of the first embodiment as illustrated in FIG. 13.

As illustrated in FIG. 13, the gate driver 10 includes a transformer 40C for transmitting a signal from the high voltage circuit 30 to the low voltage circuit 20. The transformer 40C transmits a signal from the high voltage circuit 30 toward the low voltage circuit 20 and also insulates the high voltage circuit 30 and the low voltage circuit 20. An example of the signal includes an anomaly detection signal output when an anomaly of the switching element 501 is detected. Examples of the anomaly of the switching element 501 include an anomaly of an excessive rise in temperature of the switching element 501 (temperature anomaly), an anomaly of a flow of an excessively large current in the switching element 501 (overcurrent), and an anomaly of application of an excessively high voltage to the switching element 501 (overvoltage). That is, the gate driver 10 transmits an anomaly detection signal from the high voltage circuit 30 to the low voltage circuit 20 through the transformer 40C when a temperature anomaly, an overcurrent, an overvoltage, or other anomalies of the switching element 501 is detected.

The transformer 40C includes a first transformer 41C and a second transformer 42C. The configuration of the first transformer 41C is the same as the configuration of the first transformers 41A and 41B, and the first transformer 41C includes a first coil 43C and a second coil 44C. The configuration of the second transformer 42C is the same as the configuration of the second transformers 42A and 42B, and the second transformer 42C includes a first coil 45C and a second coil 46C.

The first coil 43C is connected to a low voltage signal line 21C connected to the low voltage circuit 20 and is also connected to the ground of the low voltage circuit 20. The second coil 44C and the first coil 45C are connected through a pair of connection signal lines 11C and 12C. The second coil 46C is connected to a high voltage signal line 31C connected to the high voltage circuit 30 and is also connected to the ground of the high voltage circuit 30.

The signal output from the high voltage circuit 30 is transmitted to the low voltage circuit 20 through the second transformer 42C and the first transformer 41C. In the illustrated example, the second transformer 42C and the first transformer 41C are arranged in this order in the transmission direction of the signal.

In this way, the signals are transmitted in both directions between the low voltage circuit 20 and the high voltage circuit 30 in the modification example illustrated in FIG. 13. The signals include a first signal transmitted from the low voltage circuit 20 toward the high voltage circuit 30 and a second signal transmitted from the high voltage circuit 30 toward the low voltage circuit 20. The first signal is transmitted from the low voltage circuit 20 to the high voltage circuit 30 through the first transformer 41A (41B) and the second transformer 42A (42B) in this order. The second signal is transmitted from the high voltage circuit 30 to the low voltage circuit 20 through the second transformer 42C and the first transformer 41C in this order.

### [Supplements]

Technical ideas that can be recognized from the embodiments and the modification examples will be described below.

### (Supplement A1)

A gate driver that applies a gate voltage to a gate of a switching element, the gate driver including:

a low voltage circuit that operates when a first voltage is applied;

a high voltage circuit that operates when a second voltage higher than the first voltage is applied;

and an insulating chip, in which

the insulating chip includes
a substrate,
an insulating layer formed on the substrate,
a first insulating element including a first conductor and a second conductor embedded into the insulating layer and arranged to face each other, and
a second insulating element including a third conductor and a fourth conductor embedded into the insulating layer and arranged to face each other, and

the low voltage circuit and the high voltage circuit are connected through the first insulating element and the second insulating element connected to each other in series and are configured to transmit signals through the first insulating element and the second insulating element.

### (Supplement 2)

The gate driver according to supplement A1, in which the first conductor is arranged closer to the substrate than the second conductor in a thickness direction of the insulating layer,

the third conductor is arranged closer to the substrate than the fourth conductor in the thickness direction of the insulating layer,

the gate driver further includes a high voltage die pad provided with a high voltage circuit chip including the high voltage circuit,

the insulating chip is mounted on the high voltage die pad,

the low voltage circuit and the first conductor are electrically connected,

the high voltage circuit and the third conductor are electrically connected,

the second conductor and the fourth conductor are electrically connected, and

the first conductor is at a position farther from the substrate than the third conductor in the thickness direction of the insulating layer.

### (Supplement A3)

The gate driver according to supplement A2, in which a distance between the first conductor and the substrate is equal to or greater than a distance between the third conductor and the fourth conductor.

### (Supplement A4)

The gate driver according to supplement A2 or A3, in which the distance between the first conductor and the substrate is equal to or greater than a distance between the first conductor and the second conductor.

### (Supplement A5)

The gate driver according to any one of supplements A2 to A4, in which a distance between the first conductor and the fourth conductor is equal to or greater than the distance between the first conductor and the substrate.

### (Supplement A6)

The gate driver according to any one of supplements A2 to A5, in which the distance between the third conductor and the fourth conductor is larger than the distance between the first conductor and the second conductor.

### (Supplement A7)

The gate driver according to supplement A1, in which the insulating chip is a transformer chip including the first insulating element and the second insulating element, the first insulating element including a first transformer including a first coil as the first conductor and a second coil as the second conductor, the second insulating element including a second transformer including a third coil as the third conductor and a fourth coil as the fourth conductor,

the first coil is arranged closer to the substrate than the second coil in the thickness direction of the insulating layer,

the third coil is arranged closer to the substrate than the fourth coil in the thickness direction of the insulating layer,

the gate driver further includes a low voltage die pad provided with a low voltage circuit chip including the low voltage circuit,

the insulating chip is mounted on the low voltage die pad,

the low voltage circuit and the first coil are electrically connected,

the high voltage circuit and the third coil are electrically connected, and

the second coil and the fourth coil are electrically connected.

### (Supplement A8)

The gate driver according to supplement A7, in which the insulating chip includes a first transformer dummy pattern formed around the second coil and a second transformer dummy pattern formed around the third coil.

### (Supplement A9)

The gate driver according to supplement A8, in which the first transformer dummy pattern is at a position farther from the substrate than the first coil in the thickness direction of the insulating layer.

### (Supplement A10)

The gate driver according to supplement A9, in which the first transformer dummy pattern is at a position in line with the second coil in the thickness direction of the insulating layer.

### (Supplement A11)

The gate driver according to any one of supplements A8 to A10, in which the second transformer dummy pattern is at a position farther from the substrate than the first coil in the thickness direction of the insulating layer.

### (Supplement A12)

The gate driver according to supplement A11, in which a distance between the second transformer dummy pattern and the substrate is equal to or greater than a distance between the first coil and the second coil.

### (Supplement A13)

The gate driver according to supplement A11 or A12, in which the distance between the second transformer dummy pattern and the substrate is equal to or greater than a distance between the third coil and the fourth coil.

### (Supplement A14)

The gate driver according to any one of supplements A11 to A13, in which a distance between the third coil and the first coil is equal to or greater than a distance between the second transformer dummy pattern and the substrate.

### (Supplement A15)

The gate driver according to any one of supplements A1 to A14, in which the low voltage circuit generates a first signal for generating the gate voltage, on the basis of an external command, and the high voltage circuit generates the gate voltage on the basis of the first signal.

### (Supplement B1)

An insulating chip including:

a substrate;

an insulating layer formed on the substrate;

a first insulating element including a first conductor and a second conductor embedded into the insulating layer and arranged to face each other;

a second insulating element including a third conductor and a fourth conductor embedded into the insulating layer and arranged to face each other; and

a wire connecting the first insulating element and the second insulating element in series.

### (Supplement B2)

The insulating chip according to supplement B1, in which the insulating chip is a transformer chip including the first insulating element and the second insulating element, the first insulating element including a first transformer including a first coil as the first conductor and a second coil as the second conductor, the second insulating element including a second transformer including a third coil as the third conductor and a fourth coil as the fourth conductor.

### (Supplement B3)

The insulating chip according to supplement B1, in which the insulating chip is a capacitor chip including the first insulating element and the second insulating element, the first insulating element including a first capacitor including a first electrode plate as the first conductor and a second electrode plate as the second conductor, the second insulating element including a second capacitor including a third electrode plate as the third conductor and a fourth electrode plate as the fourth conductor.

### (Supplement B4)

An insulating module including:

the insulating chip according to any one of supplements B1 to B3; and

a die pad provided with the insulating chip.

### (Supplement B5)

The insulating module according to supplement B4, in which the insulating module is used to insulate a low voltage circuit and a high voltage circuit included in a gate driver.

### (Supplement B6)

A low voltage circuit unit including:

the insulating module according to supplement B5; and

the low voltage circuit.

### (Supplement B7)

A high voltage circuit unit including:

the insulating module according to supplement B5; and

the high voltage circuit.

What is claimed is:

1. An insulating chip that is able to connect a low voltage circuit and a high voltage circuit, wherein
the insulating chip includes
a substrate,
an insulating layer formed on the substrate,
a first insulating element including a first conductor and a second conductor embedded into the insulating layer and arranged to face each other, and
a second insulating element including a third conductor and a fourth conductor embedded into the insulating layer and arranged to face each other, and
the low voltage circuit and the high voltage circuit are connected through the first insulating element and the second insulating element connected to each other in series and are configured to transmit signals through the first insulating element and the second insulating element.

2. The insulating chip according to claim 1, wherein
the first conductor is arranged closer to the substrate than the second conductor in a thickness direction of the insulating layer,
the third conductor is arranged closer to the substrate than the fourth conductor in the thickness direction of the insulating layer,
the gate driver further includes a low voltage die pad provided with a low voltage circuit chip including the low voltage circuit,
the insulating chip is mounted on the low voltage die pad,
the low voltage circuit and the first conductor are electrically connected,
the high voltage circuit and the third conductor are electrically connected, and
the second conductor and the fourth conductor are electrically connected.

3. The insulating chip according to claim 2, wherein
the third conductor is at a position farther from the substrate than the first conductor in the thickness direction of the insulating layer.

4. The insulating chip according to claim 3, wherein
a distance between the third conductor and the substrate is equal to or greater than a distance between the first conductor and the second conductor.

5. The insulating chip according to claim 3, wherein
a distance between the third conductor and the substrate is equal to or greater than a distance between the third conductor and the fourth conductor.

6. The insulating chip according to claim 3, wherein
a distance between the third conductor and the first conductor is equal to or greater than a distance between the third conductor and the substrate.

7. The insulating chip according to claim 3, wherein
a distance between the first conductor and the second conductor is larger than a distance between the third conductor and the fourth conductor.

8. The insulating chip according to claim 1 wherein
the second conductor and the fourth conductor are arranged at positions in line with each other in a thickness direction of the insulating layer.

9. The insulating chip according to claim 1, wherein
the substrate is a substrate formed from a material containing Si.

10. The insulating chip according to claim 1, wherein
the substrate is a substrate formed from a material containing glass.

11. The insulating chip according to claim 1, wherein
the substrate is a substrate including a first semiconductor layer, a second semiconductor layer, and a semiconductor oxide layer arranged between the first semiconductor layer and the second semiconductor layer.

12. The insulating chip according to claim 11, wherein
a dividing band that contains an insulating material and that goes through the second semiconductor layer to reach the semiconductor oxide layer is formed on the second semiconductor layer, and
the dividing band is arranged between the first conductor and the third conductor as viewed from a thickness direction of the insulating layer and is provided to divide the second semiconductor layer into a first divided semiconductor layer facing the first conductor and a second divided semiconductor layer facing the third conductor.

13. The insulating chip according to claim 9, wherein
the first conductor and the third conductor are arranged at positions in line with each other in a thickness direction of the insulating layer.

14. The insulating chip according to claim 1, wherein
the first insulating element includes a first transformer including a first coil as the first conductor and a second coil as the second conductor, and
the second insulating element includes a second transformer including a third coil as the third conductor and a fourth coil as the fourth conductor.

15. The insulating chip according to claim 1, wherein
the first insulating element includes a first capacitor including a first electrode plate as the first conductor and a second electrode plate as the second conductor, and
the second insulating element includes a second capacitor including a third electrode plate as the third conductor and a fourth electrode plate as the fourth conductor.
